(19) United States
(12) Patent Application Publication
(10) Pub. No.: US 2025/0275133 A1
(43) Pub. Date: Aug. 28, 2025

(54) THREE-DIMENSIONAL MEMORY DEVICE CONTAINING A REPLACEMENT ETCH-STOP LINER FOR LAYER CONTACT VIA STRUCTURES AND METHODS FOR FORMING THE SAME

(71) Applicant: SANDISK TECHNOLOGIES LLC, ADDISON, TX (US)

(72) Inventors: Masato NOGUCHI, Yokkaichi (JP); Ryo NAKAMURA, Yokkaichi (JP)

(21) Appl. No.: 18/588,849

(22) Filed: Feb. 27, 2024

(51) Int. Cl. H10B 43/27

(52) U.S. Cl. CPC H10B 43/27

(57) ABSTRACT

A device structure includes an alternating stack of insulating layers and electrically conductive layers that alternate along a vertical direction, where lateral extents of the electrically conductive layers vary in a staircase region, memory openings vertically extending through the alternating stack, memory opening fill structures located in the memory openings, where each of the memory opening fill structures includes a respective vertical stack of memory elements and a vertical semiconductor channel, and a continuous metal oxide etch-stop and blocking dielectric layer including blocking dielectric layer portions and an etch-stop dielectric layer portion, where the etch-stop dielectric layer portion continuously extends over at least a portion of the alternating stack in the staircase region with a stepped vertical cross-sectional profile.

### FIELD

The present disclosure relates generally to the field of semiconductor devices, and particularly to a three-dimensional memory device containing a replacement etch-stop liner as an etch-stop structure for layer contact via structures and methods for forming the same.

### BACKGROUND

A three-dimensional memory device can include an alternating stack of insulating layers and electrically conductive layers. A reliable method is desired for forming layer contact via structures for each of the electrically conductive layers without generating electrical shorts between neighboring pairs of electrically conductive layers.

### SUMMARY

According to an aspect of the present disclosure, a device structure includes an alternating stack of insulating layers and electrically conductive layers that alternate along a vertical direction, where lateral extents of the electrically conductive layers vary in a staircase region, memory openings vertically extending through the alternating stack, memory opening fill structures located in the memory openings, where each of the memory opening fill structures includes a respective vertical stack of memory elements and a vertical semiconductor channel, and a continuous metal oxide etch-stop and blocking dielectric layer including blocking dielectric layer portions and an etch-stop dielectric layer portion, where the etch-stop dielectric layer portion continuously extends over at least a portion of the alternating stack in the staircase region with a stepped vertical cross-sectional profile.

According to another aspect of the present disclosure, a method of forming a device structure comprises: forming an alternating stack of insulating layers and sacrificial material layers over a substrate; forming stepped surfaces by pattering the alternating stack; forming a stepped sacrificial liner on the stepped surfaces of the alternating stack; forming a retro-stepped dielectric material portion over the stepped sacrificial liner; forming memory stack structures through the alternating stack; forming a continuous void including laterally-extending cavities and a staircase-shaped cavity by removing the sacrificial material layers and the stepped sacrificial liner, wherein the laterally-extending cavities comprise voids formed by removal of the sacrificial material layers and the staircase-shaped cavity comprises a void formed by removal of the stepped sacrificial liner; forming a continuous etch-stop and blocking dielectric layer including blocking dielectric layer portions and an etch-stop dielectric layer portion having a stepped vertical cross-sectional profile, and each of the blocking dielectric layer portions is formed in a peripheral region of a respective one of the laterally-extending cavities; and forming electrically conductive layers in remaining unfilled volumes of the laterally-extending cavities.

### BRIEF DESCRIPTION OF THE DRAWINGS

FIG. 1 is a vertical cross-sectional view of an exemplary structure for forming a memory die after formation of a first alternating stack of first insulating layers and first sacrificial material layers, and a first hard mask layer over a substrate according to an embodiment of the present disclosure.

FIG. 2 is a vertical cross-sectional view of the exemplary structure after formation of first stepped surfaces and a first stepped sacrificial liner according to an embodiment of the present disclosure.

FIG. 3 is a vertical cross-sectional view of the exemplary structure after formation of a first retro-stepped dielectric material portion according to an embodiment of the present disclosure.

FIG. 4A is a vertical cross-sectional view of the exemplary structure after forming first-tier memory openings, first-tier support openings, and first-tier lateral isolation trenches according to an embodiment of the present disclosure.

FIG. 4B is a top-down view of the exemplary structure of FIG. 4A. The vertical plane A-A′ is the cut plane of the vertical cross-sectional view of FIG. 4A.

FIG. 5 is a vertical cross-sectional view of the exemplary structure after formation of first-tier sacrificial fill material portions according to an embodiment of the present disclosure.

FIG. 6 is a vertical cross-sectional view of the exemplary structure after formation of a second alternating stack of second insulating layers and second sacrificial material layers, second stepped surfaces, a second stepped sacrificial liner, and a second retro-stepped dielectric material portion according to an embodiment of the present disclosure.

FIG. 7 is a vertical cross-sectional view of the exemplary structure after forming second-tier memory openings, second-tier support openings, and second-tier lateral isolation trenches according to an embodiment of the present disclosure.

FIG. 8A is a vertical cross-sectional view of the exemplary structure after formation of second-tier sacrificial fill material portions according to an embodiment of the present disclosure.

FIG. 8B is a top-down view of the exemplary structure of FIG. 8A. The vertical plane A-A′ is the cut plane of the vertical cross-sectional view of FIG. 8A.

FIG. 9A is a vertical cross-sectional view of the exemplary structure after formation of third-tier sacrificial fill material portions according to an embodiment of the present disclosure.

FIG. 9B is a top-down view of the exemplary structure of FIG. 9A. The vertical plane A-A′ is the cut plane of the vertical cross-sectional view of FIG. 9A.

FIG. 10 is a vertical cross-sectional view of the exemplary structure after formation of support pillar structures according to an embodiment of the present disclosure.

FIG. 11 is a vertical cross-sectional view of the exemplary structure after formation of inter-tier memory openings according to an embodiment of the present disclosure.

FIGS. 12A-12D are sequential vertical cross-sectional views of a region around an inter-tier memory opening during formation of a memory opening fill structure according to an embodiment of the present disclosure.

FIG. 13 is a vertical cross-sectional view of the exemplary structure after formation of memory opening fill structures according to an embodiment of the present disclosure.

FIG. 14A is a vertical cross-sectional view of the exemplary structure after formation of a contact-level dielectric layer and contact-level trenches according to an embodiment of the present disclosure.

FIG. 14B is a top-down view of the exemplary structure of FIG. 14A. The vertical plane A-A′ is the cut plane of the vertical cross-sectional view of FIG. 14A.

FIG. 15A is a vertical cross-sectional view of the exemplary structure after formation of lateral isolation trenches according to an embodiment of the present disclosure.

FIG. 15B is a magnified view of a region around third stepped surfaces of the exemplary structure of FIG. 15A.

FIG. 15C is a magnified view of a region around a memory opening fill structure of the exemplary structure of FIG. 15A.

FIG. 15D is a magnified view of a region around a support pillar structure of the exemplary structure of FIG. 15A.

FIG. 16A is a vertical cross-sectional view of the exemplary structure after formation of laterally-extending cavities according to an embodiment of the present disclosure.

FIG. 16B is a magnified view of a region around third stepped surfaces of the exemplary structure of FIG. 16A.

FIG. 16C is a magnified view of a region around a memory opening fill structure of the exemplary structure of FIG. 16A.

FIG. 16D is a magnified view of a region around a support pillar structure of the exemplary structure of FIG. 16A.

FIG. 17A is a vertical cross-sectional view of the exemplary structure after depositing a continuous etch-stop and blocking dielectric layer according to an embodiment of the present disclosure.

FIG. 17B is a magnified view of a region around third stepped surfaces of the exemplary structure of FIG. 17A.

FIG. 17C is a magnified view of a region around a memory opening fill structure of the exemplary structure of FIG. 17A.

FIG. 17D is a magnified view of a region around a support pillar structure of the exemplary structure of FIG. 17A.

FIG. 18A is a vertical cross-sectional view of the exemplary structure after isotropically recessing the continuous etch-stop and blocking dielectric layer according to an embodiment of the present disclosure.

FIG. 18B is a magnified view of a region around third stepped surfaces of the exemplary structure of FIG. 18A.

FIG. 18C is a magnified view of a region around a memory opening fill structure of the exemplary structure of FIG. 18A.

FIG. 18D is a magnified view of a region around a support pillar structure of the exemplary structure of FIG. 18A.

FIG. 19A is a vertical cross-sectional view of the exemplary structure after depositing electrically conductive layers in remaining volumes of the laterally-extending cavities according to an embodiment of the present disclosure.

FIG. 19B is a magnified view of a region around third stepped surfaces of the exemplary structure of FIG. 19A.

FIG. 19C is a magnified view of a region around a memory opening fill structure of the exemplary structure of FIG. 19A.

FIG. 19D is a magnified view of a region around a support pillar structure of the exemplary structure of FIG. 19A.

FIG. 20 is a vertical cross-sectional view of the exemplary structure after formation of lateral isolation trench fill structures according to an embodiment of the present disclosure.

FIG. 21 is a vertical cross-sectional view of the exemplary structure after formation of layer contact via cavities according to an embodiment of the present disclosure.

FIG. 22 is a vertical cross-sectional view of the exemplary structure after formation of drain contact via cavities according to an embodiment of the present disclosure.

FIG. 23A is a vertical cross-sectional view of the exemplary structure after formation of layer contact via structures and drain contact via structures according to an embodiment of the present disclosure.

FIG. 23B is a top-down view of the exemplary structure of FIG. 23A. The hinged vertical plane A-A′ is a cut plane of the vertical cross-sectional view of FIG. 23A.

FIG. 24 is a vertical cross-sectional view of the exemplary structure after formation of memory-side dielectric material layers and memory-side metal interconnect structures according to an embodiment of the present disclosure.

FIG. 25 is a vertical cross-sectional view of the exemplary structure after attaching a logic die to a memory die according to an embodiment of the present disclosure.

FIG. 26 is a vertical cross-sectional view of the exemplary structure after removal of a carrier substrate according to an embodiment of the present disclosure.

FIG. 27A is a vertical cross-sectional view of the exemplary structure after formation of a source layer, a backside dielectric layer, and backside contact pads according to an embodiment of the present disclosure.

FIG. 27B is a magnified view of a region around a memory opening fill structure of the exemplary structure of FIG. 27A.

FIG. 28 is a vertical cross-sectional view of a first alternative configuration of the exemplary structure according to an embodiment of the present disclosure.

FIG. 29 is a vertical cross-sectional view of a second alternative configuration of the exemplary structure according to an embodiment of the present disclosure.

FIG. 30 is a vertical cross-sectional view of a third alternative configuration of the exemplary structure according to an embodiment of the present disclosure.

### DETAILED DESCRIPTION

Embodiments of the disclosure can be employed to form semiconductor devices, such as three-dimensional memory devices that include a replacement metal oxide etch-stop liner for forming layer contact via structures (e.g., word line contact via structures).

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

As discussed above, the embodiments of the present disclosure are directed to a memory device employing a replacement etch-stop liner as an etch-stop structure for layer contact via structures and methods for forming the same. Various aspects of the present disclosure are now described with reference to accompanying drawings.

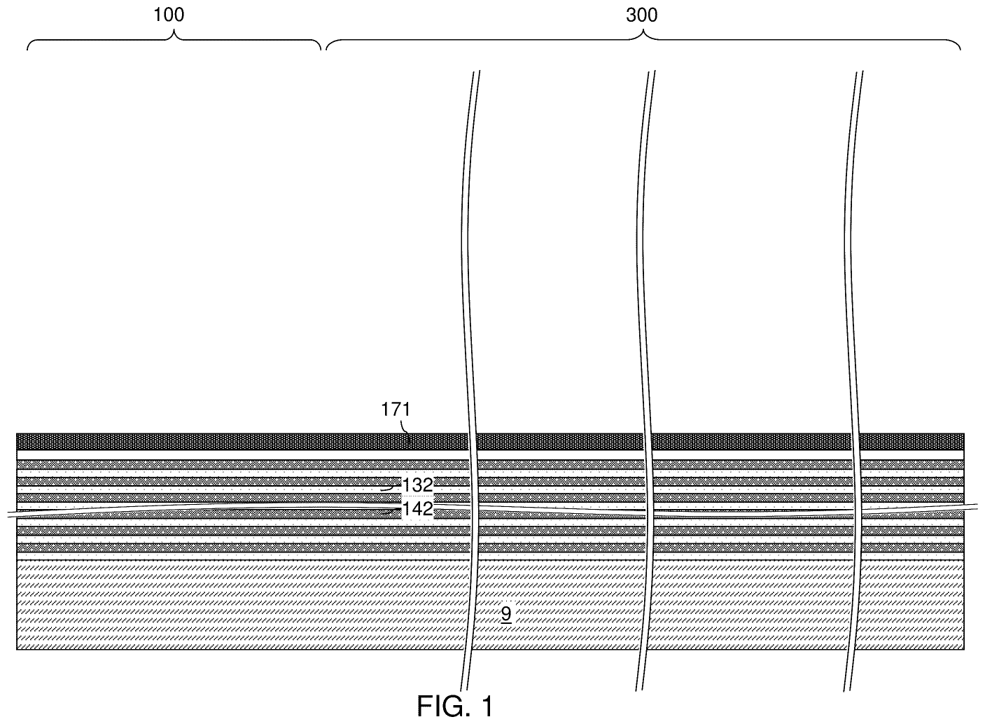

Referring to FIG. 1, an exemplary structure according to an embodiment of the present disclosure is illustrated. The exemplary structure comprises a substrate, such as a carrier substrate 9, which may be a semiconductor substrate. For example, the carrier substrate 9 may comprise a commercially available silicon wafer. Alternatively, the carrier substrate 9 may comprise any material that may be removed selective the materials of overlying material layers which are subsequently formed.

A first alternating stack of first insulating layers 132 and first sacrificial material layers 142 can be formed over the carrier substrate 9. The first insulating layers 132 comprise an insulating material, such as undoped silicate glass (i.e., silicon oxide) or a doped silicate glass, and the first sacrificial material layers 142 comprise a sacrificial material, such as silicon nitride or a silicon-germanium alloy. In one embodiment, the first insulating layers 132 may comprise silicon oxide layers, and the first sacrificial material layers 142 may comprise silicon nitride layers. The first alternating stack (132, 142) may comprise multiple repetitions of a unit layer stack including a first insulating layer 132 and a first sacrificial material layer 142. The total number of repetitions of the unit layer stack within the first alternating stack (132, 142) may be, for example, in a range from 8 to 1,024, such as from 32 to 256, although lesser and greater number of repetitions may also be employed.

Each of the first insulating layers 132 may have a thickness in a range from 10 nm to 60 nm, such as from 15 nm to 40 nm, although lesser and greater thicknesses may also be employed. Each of the first sacrificial material layers 142 may have a thickness in a range from 15 nm to 70 nm, such as from 20 nm to 50 nm, although lesser and greater thicknesses may also be employed.

An optional first hard mask layer 171 can be formed over the first alternating stack (132, 142). The first hard mask layer 171 comprises a material that can be employed as a planarization stopper material during a subsequent chemical mechanical polishing (CMP) process. For example, the first hard mask layer 171 comprises silicon nitride or titanium nitride. In one embodiment, the first hard mask layer 171 may have a thickness in a range from 60 nm to 400 nm, such as from 100 nm to 300 nm, although lesser and greater thicknesses may also be employed.

The exemplary structure comprises a memory array region 100 in which a three-dimensional array of memory elements is to be subsequently formed, and a contact (i.e., staircase) region 300 having stepped surfaces of the alternating stack in which layer contact via structures contacting electrically conductive layers (e.g., word lines and select gate electrodes) are to be subsequently formed.

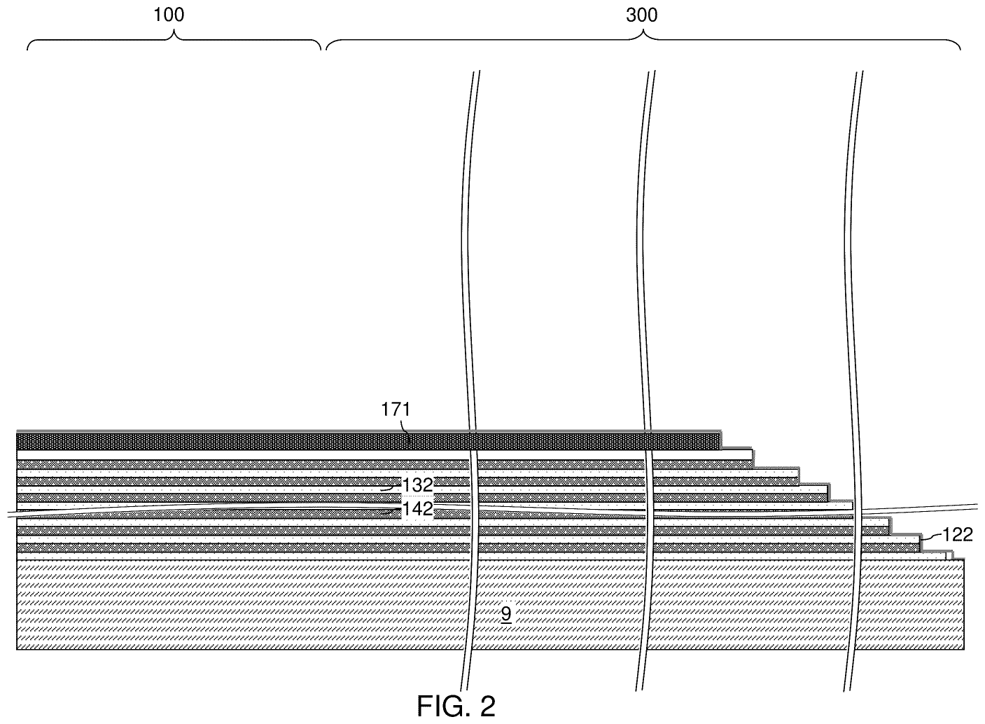

Referring to FIG. 2, first stepped surfaces are formed in the contact (i.e., staircase) region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first alternating stack (132, 142) and the first hard mask layer 171 are removed through formation of the first stepped surfaces. A “stepped cavity” refers to a cavity having stepped surfaces.

The first stepped cavity can have various first stepped surfaces such that the horizontal cross-sectional shape of the first stepped cavity changes in steps as a function of the vertical distance from the top surface of the carrier substrate 9. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each first sacrificial material layer 142 other than a topmost first sacrificial material layer 142 within the first alternating stack (132, 142) laterally extends farther than any overlying first sacrificial material layer 142 within the first alternating stack (132, 142) in the terrace region. The first stepped surfaces of the first alternating stack (132, 142) continuously extend from a bottommost layer within the first alternating stack (132, 142) to the first hard mask layer 171. Generally, the first stepped surfaces continuously extend from a bottommost layer within the first alternating stack (132, 142) at least to a topmost layer within the first alternating stack (132, 142).

A sacrificial liner material is conformally deposited over the first stepped surfaces and the first hard mask layer 171 to form a first stepped sacrificial liner 122. The first stepped sacrificial liner 122 comprises a material that may be subsequently removed selective to the material of the first insulating layers 132. In one embodiment, the first stepped sacrificial liner 122 comprises the same material as the first sacrificial material layers 142. In one embodiment, first stepped sacrificial liner 122 and the first sacrificial material layers 142 comprise and/or consist essentially of silicon nitride. The thickness of the first stepped sacrificial liner 122 is less than the thickness of each first insulating layer 132, and is less than the thickness of each first sacrificial material layer 142. In one embodiment, the thickness of the first stepped sacrificial liner 122 may be in a range from 3 nm to 20 nm, such as from 5 nm to 15 nm, although lesser and greater thicknesses may also be employed.

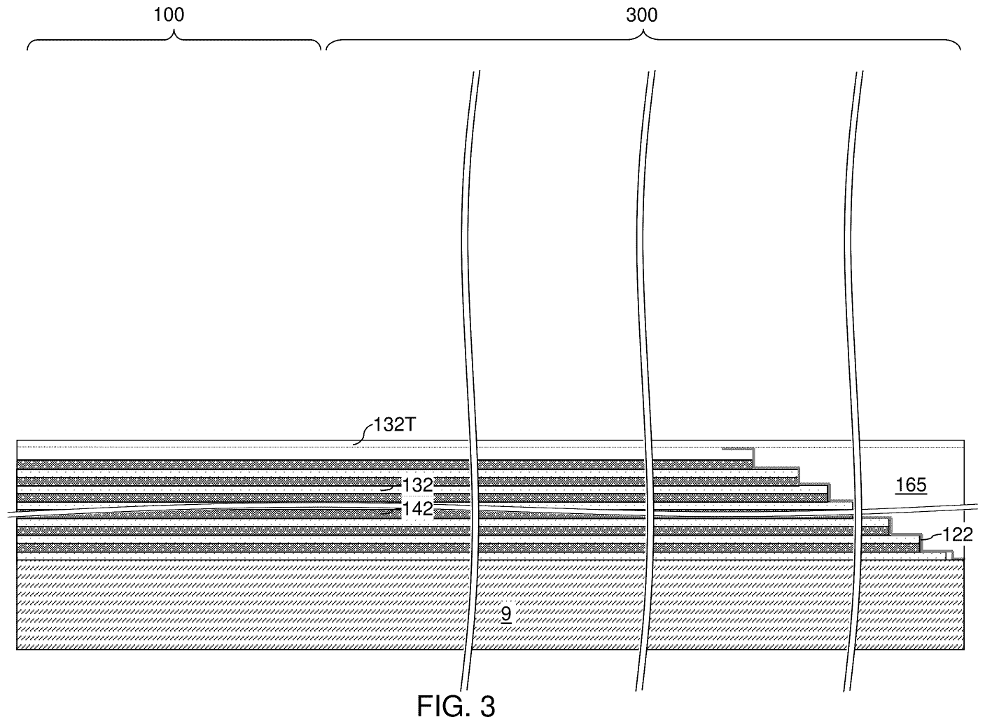

Referring to FIG. 3, a first retro-stepped dielectric material portion 165 (i.e., an insulating fill material portion) can be formed in the first stepped cavity and over the first stepped sacrificial liner 122 by deposition of a dielectric material therein. For example, a dielectric material such as silicon oxide can be deposited in the first stepped cavity. Excess portions of the deposited dielectric material can be removed from above the top surface of the first hard mask layer 171, for example, by chemical mechanical polishing (CMP) process. Portions of the first stepped sacrificial liner 122 that overlie the first hard mask layer 171 can be collaterally removed during the CMP process. The remaining portion of the deposited dielectric material filling the first stepped cavity constitutes the first retro-stepped dielectric material portion 165. As used herein, a “stepped” element refers to an element that has first stepped surfaces and a horizontal cross-sectional area that increases monotonically as a function of a vertical distance from a top surface of a substrate on which the element is present. If silicon oxide is employed for the first retro-stepped dielectric material portion 165, the silicon oxide of the first retro-stepped dielectric material portion 165 may, or may not, be doped with dopants such as B, P, and/or F.

Further, a recess etch process can be performed to vertically recess a top surface of the first retro-stepped dielectric material portion 165. The recess depth of the recess etch process may be the same as the thickness of the first hard mask layer 171. Subsequently, the first hard mask layer 171 can be removed by performing an etch process that etches the material of the first hard mask layer 171 selective to the material of the first retro-stepped dielectric material portion 165. For example, if the first retro-stepped dielectric material portion 165 comprises silicon oxide and if the first hard mask layer 171 comprises silicon nitride, a wet etch process employing hot phosphoric acid can be performed to remove the first hard mask layer 171. A portion of the first stepped sacrificial liner 122 that overlies the horizontal plane including the top surface of the first retro-stepped dielectric material portion 165 can be collaterally removed during removal of the first hard mask layer 171. In one embodiment, the top surface of the first retro-stepped dielectric material portion 165 and a top surface of the topmost first insulating layer 132 within the first alternating stack (132, 142) can be located within a same horizontal plane. The first stepped sacrificial liner 122 can be located between the first retro-stepped dielectric material portion 165 and the combination of the first alternating stack (132, 142) and the carrier substrate 9. An optional additional insulating layer 132T may be deposited over the first retro-stepped dielectric material portion 165, the combination of the first alternating stack (132, 142), and the first stepped sacrificial liner 122.

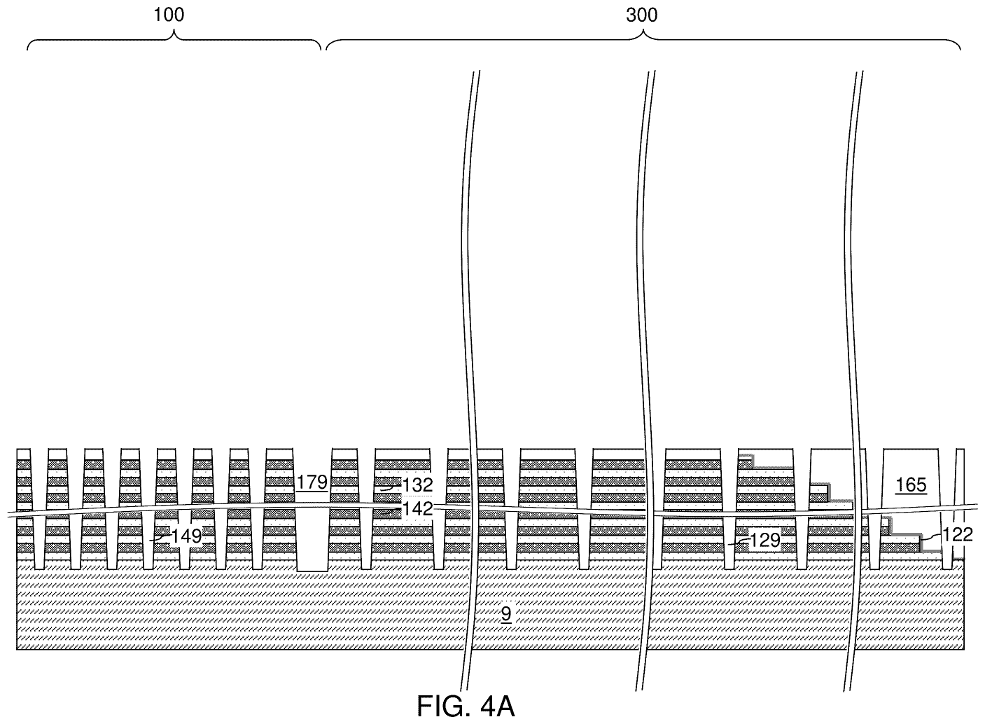

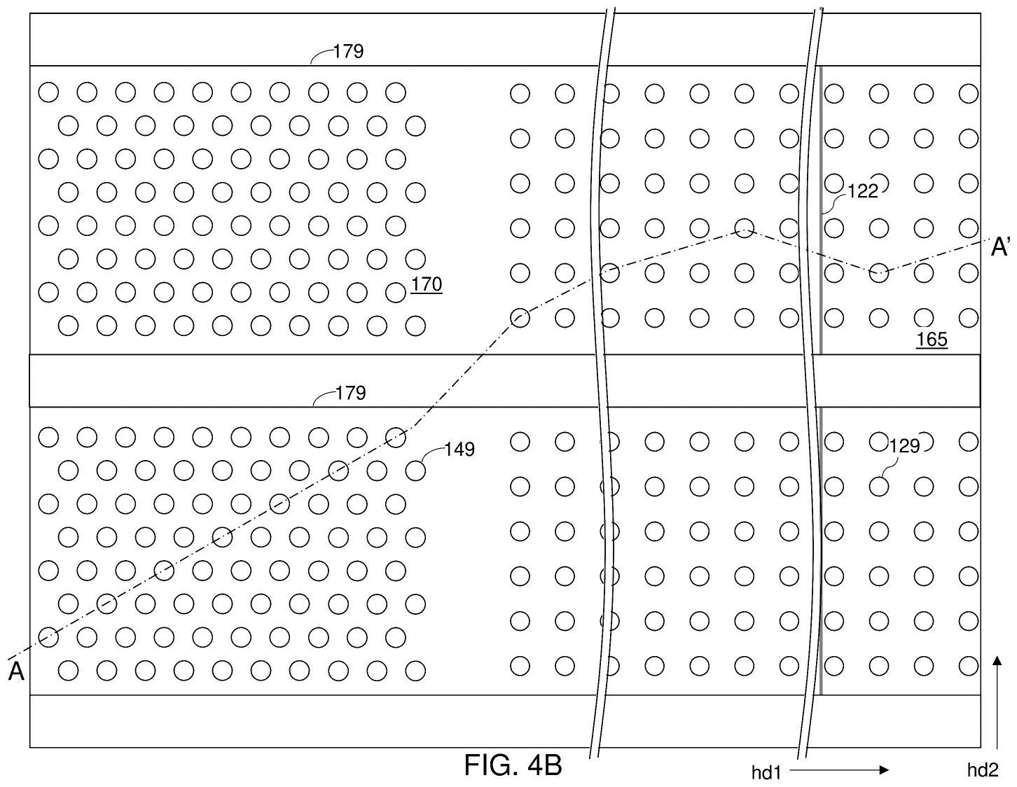

Referring to FIGS. 4A and 4B, a first etch mask layer (not shown) can be formed over the first alternating stack (132, 142) and the first retro-stepped dielectric material portion 165. The first etch mask layer may comprise a carbon-based material, such as a carbon-based patterning film as known in the art. A photoresist layer (not shown) can be formed above the first etch mask layer, and can be lithographically patterned to form various openings therein. A first anisotropic etch process can be performed to transfer the pattern of the openings in the photoresist layer through the first etch mask layer, the first alternating stack (132, 142), and the first retro-stepped dielectric material portion 165. The photoresist layer and an upper portion of the first etch mask layer can be collaterally removed during the first anisotropic etch process. Remaining portions of the first etch mask layer can be removed after the first anisotropic etch process, for example, by ashing.

The various openings may comprise first-tier memory openings 149 that are formed in the memory array region 100, first-tier support openings 129 that are formed in the contact region 300, and optionally first-tier lateral isolation trenches 179 that laterally extend along a first horizontal direction (e.g., word line direction) hd1 across the memory array region 100 and the contact region 300. Each of the first-tier memory openings 149, the first-tier support openings 129, and the first-tier lateral isolation trenches 179 can vertically extend through the first alternating stack (132, 142) into an upper portion of the carrier substrate 9.

The first-tier support openings 129 may have a maximum diameter in a range from 50 nm to 400 nm, such as from 70 nm to 300 nm, although lesser and greater maximum diameters may be employed. The first-tier memory openings 149 may have a maximum diameter in a range from 50 nm to 400 nm, such as from 70 nm to 300 nm, although lesser and greater maximum diameters may be employed. The first-tier lateral isolation trenches 179 may have a width in a range from 150 nm to 1,000 nm, such as from 200 nm to 600 nm, although lesser and greater widths may also be employed. The first-tier support openings 129 and the first-tier memory openings 149 may be discrete openings. The first-tier lateral isolation trenches 179 may laterally extend along a first horizontal direction hd1 with a uniform width along a second horizontal direction (e.g., bit line direction) hd2 that is perpendicular to the first horizontal direction hd1.

In one embodiment, the memory array region 100 may be laterally spaced apart from the contact region 300 along the first horizontal direction hd1. The first-tier memory openings 149 may comprise rows of first-tier memory openings 149 that are arranged along the first horizontal direction hd1 and laterally spaced apart along the second horizontal direction hd2. Multiple clusters (e.g., memory block areas) of first-tier memory openings 149, each containing a respective two-dimensional periodic array of first-tier memory openings 149, may be formed in the memory array region 100. The clusters of first-tier memory openings 149 may be laterally spaced apart along the second horizontal direction hd2.

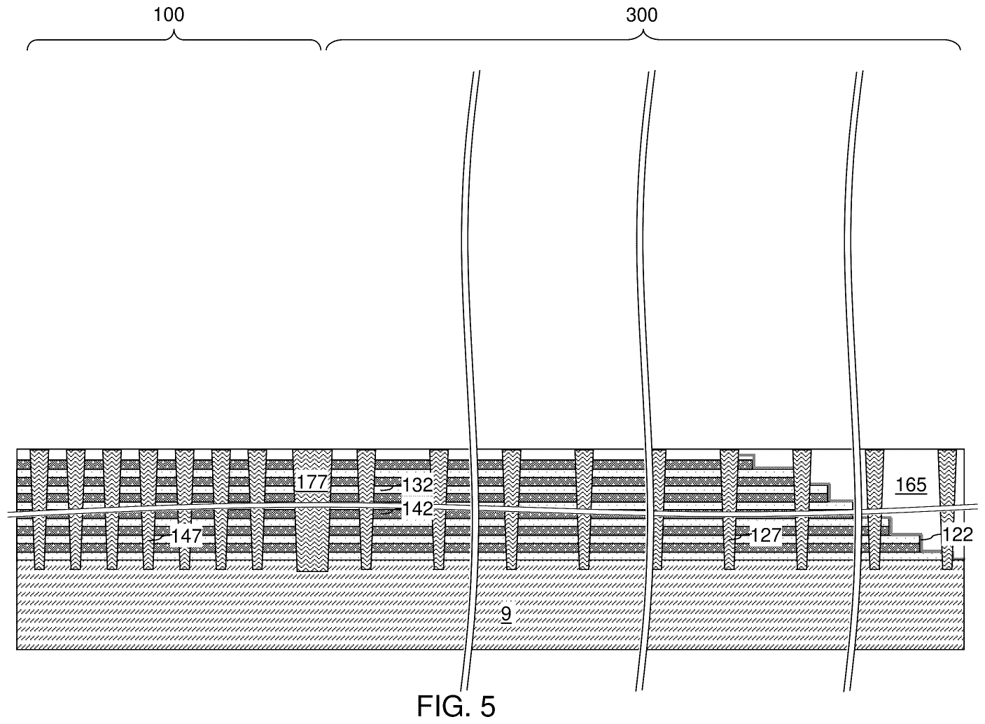

Referring to FIG. 5, an optional etch-stop liner (not shown) and a first sacrificial fill material can be deposited in the first-tier memory openings 149, the first-tier support openings 129, and the first-tier lateral isolation trenches 179. The optional etch-stop liner (if present) comprises a thin silicon oxide layer having a thickness in a range from 1 nm to 6 nm. The first sacrificial fill material may comprise a carbon-based material, such as amorphous carbon or diamond-like carbon.

A planarization process can be performed to remove portions of the first sacrificial fill material from above the horizontal plane including the top surface of the first alternating stack (132, 142). Remaining portions of the first sacrificial fill material that fill the first-tier memory openings 149, the first-tier support openings 129, and the first-tier lateral isolation trenches 179 constitute first-tier sacrificial opening fill material portions (147, 127, 177). The first-tier sacrificial opening fill material portions (147, 127, 177) comprise first-tier sacrificial memory opening fill material portions 147 that are formed in the first-tier memory openings 149, first-tier sacrificial opening fill material portions 127 that are formed in the first-tier support openings 129, and optional first-tier sacrificial lateral isolation trench fill material portions 177 that are formed in the first-tier lateral isolation trenches 179.

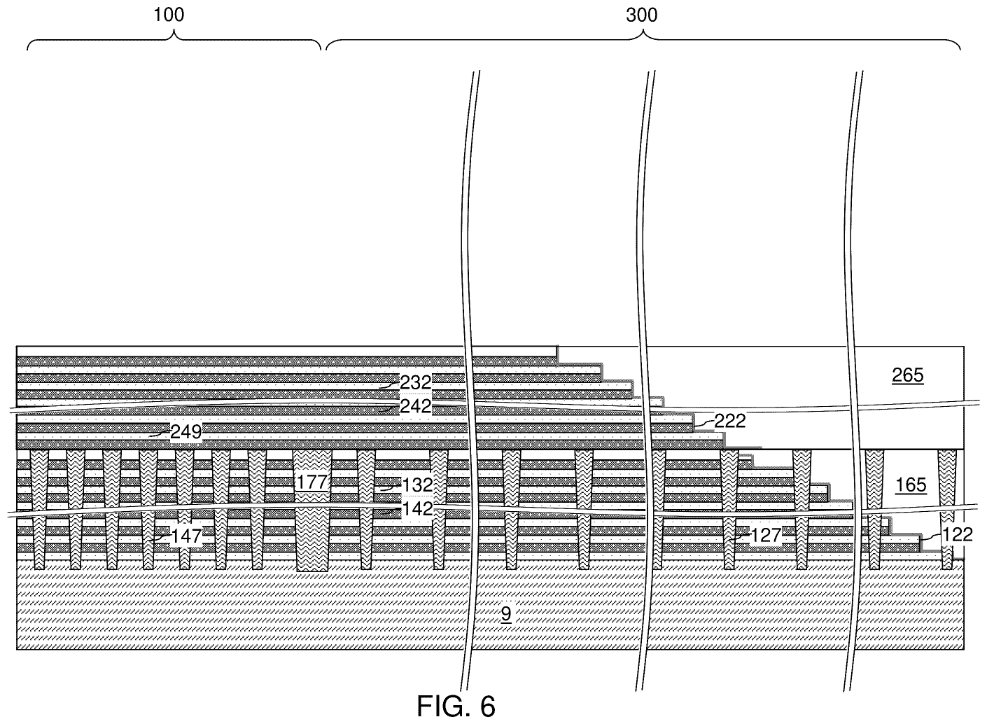

Referring to FIG. 6, the processing steps described with reference to FIGS. 1-3 can be optionally performed again with any needed changes to form a second alternating stack of second insulating layers 232 and second sacrificial material layers 242, a second stepped sacrificial liner 222, and a second retro-stepped dielectric material portion 265. The second alternating stack (232, 242) may comprise multiple repetitions of a unit layer stack including a second insulating layer 232 and a second sacrificial material layer 242. The total number of repetitions of the unit layer stack within the second alternating stack (232, 242) may be, for example, in a range from 8 to 1,024, such as from 32 to 256, although lesser and greater number of repetitions may also be employed. The area of the second stepped surfaces may be located in the contact region 300, but may be laterally offset along the first horizontal direction hd1 toward the memory array region 100 relative to the area of the first stepped surfaces. Each second insulating layer 232 may have the same material composition and the same thickness as each first insulating layer 132. Each second sacrificial material layer 242 may have the same material composition and the same thickness as each first sacrificial material layer 142. The second stepped sacrificial liner 222 may have the same material composition and the same thickness as the first stepped sacrificial liner 122. The second retro-stepped dielectric material portion 265 may have the same material composition as the first retro-stepped dielectric material portion 165. A horizontal portion of the second stepped sacrificial liner 222 located over the first retro-stepped dielectric material portion 165 may be removed by photolithographic masking and etching. Alternatively, the formation of the second alternating stack (232, 242) may be omitted if the memory device includes only one tier.

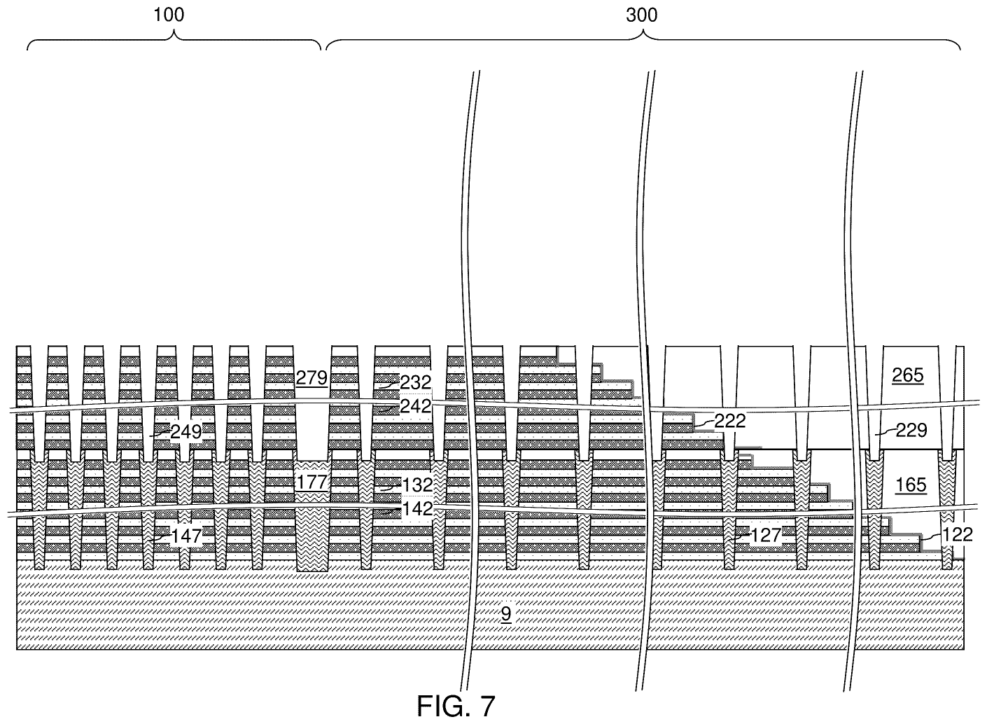

Referring to FIG. 7, the processing steps described with reference to FIGS. 4A and 4B can be performed with any needed changes to form various openings through the second alternating stack (232, 242), the second retro-stepped dielectric material portion 265, and the second stepped sacrificial liner 222. The pattern of the openings through the second alternating stack (232, 242), the second retro-stepped dielectric material portion 265, and the second stepped sacrificial liner 222 may be the same as the pattern of the openings through the first alternating stack (132, 142) that are formed at the processing steps described with reference to FIGS. 4A and 4B. The openings that are formed through the second alternating stack (232, 242), the second retro-stepped dielectric material portion 265, and the second stepped sacrificial liner 222 may comprise second-tier memory openings 249 that are formed in the memory array region 100, second-tier support openings 229 that are formed in the contact region 300, and optionally second-tier lateral isolation trenches 279 that laterally extend along the first horizontal direction hd1 across the memory array region 100 and the contact region 300. Each of the second-tier memory openings 249, the second-tier support openings 229, and the second-tier lateral isolation trenches 279 can vertically extend through the second alternating stack (232, 242) and/or the second retro-stepped dielectric material portion 265, and may vertically extend into an upper portion of the first-tier sacrificial opening fill material portions (147, 127, 177).

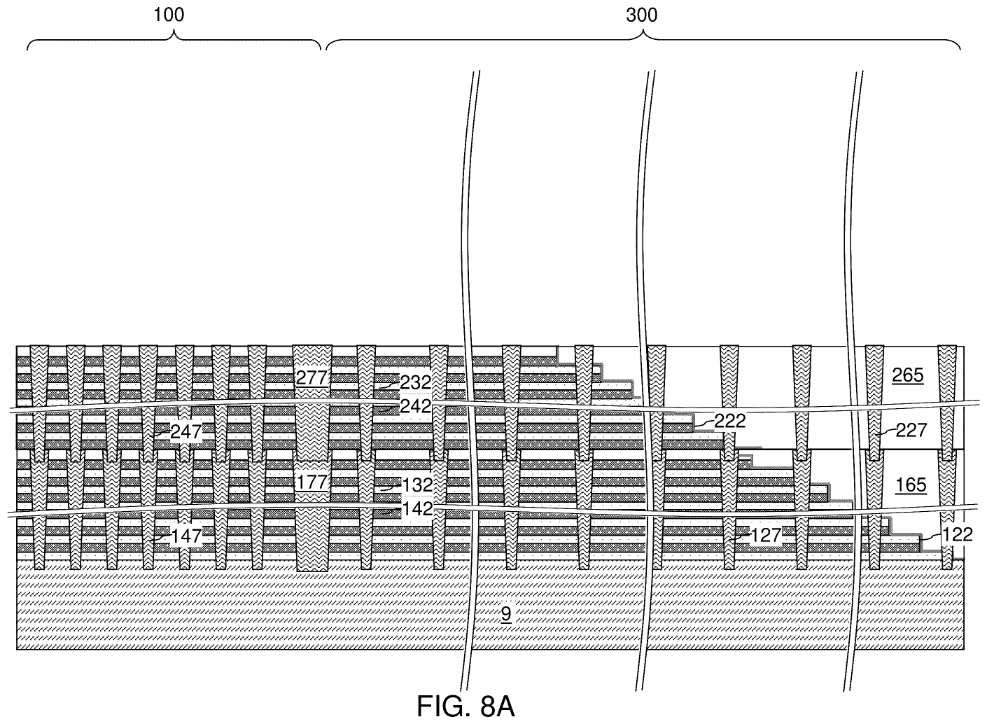

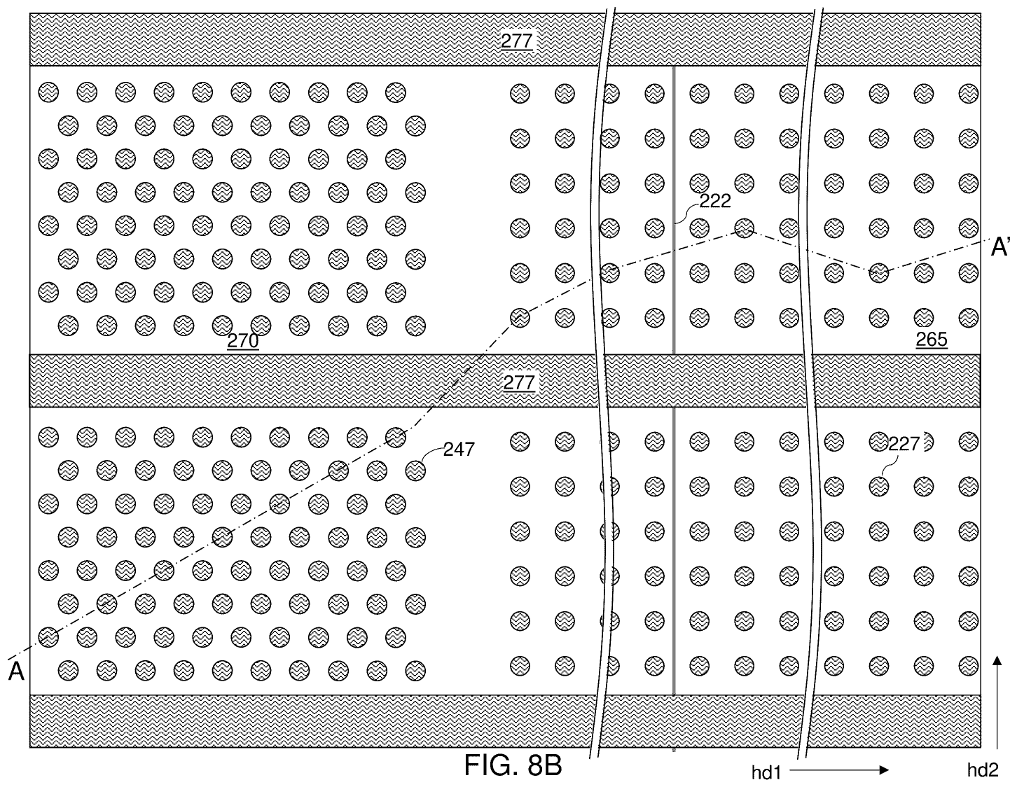

Referring to FIGS. 8A and 8B, the processing steps described with reference to FIG. 5 can be performed with any needed changes to form various second-tier sacrificial opening fill material portions (247, 227, 277). The second-tier sacrificial opening fill material portions (247, 227, 277) comprise second-tier sacrificial memory opening fill material portions 247 that are formed in the second-tier memory openings 249, second-tier sacrificial support opening fill material portions 227 that are formed in the second-tier support openings 229, and optional second-tier sacrificial lateral isolation trench fill material portions 277 that are formed in the second-tier lateral isolation trenches 279.

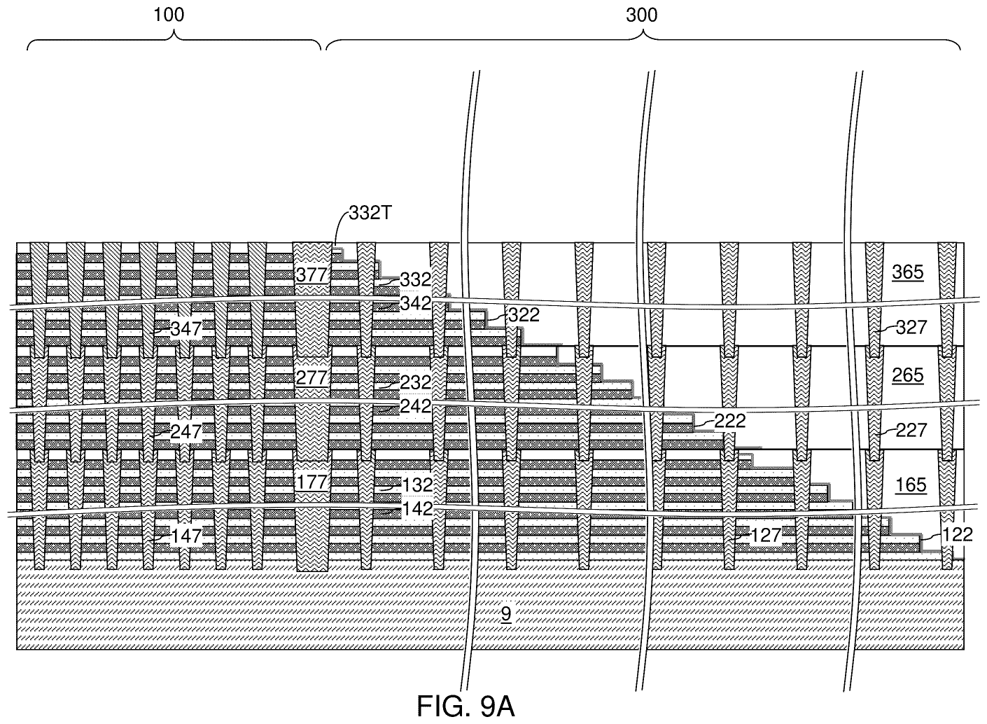

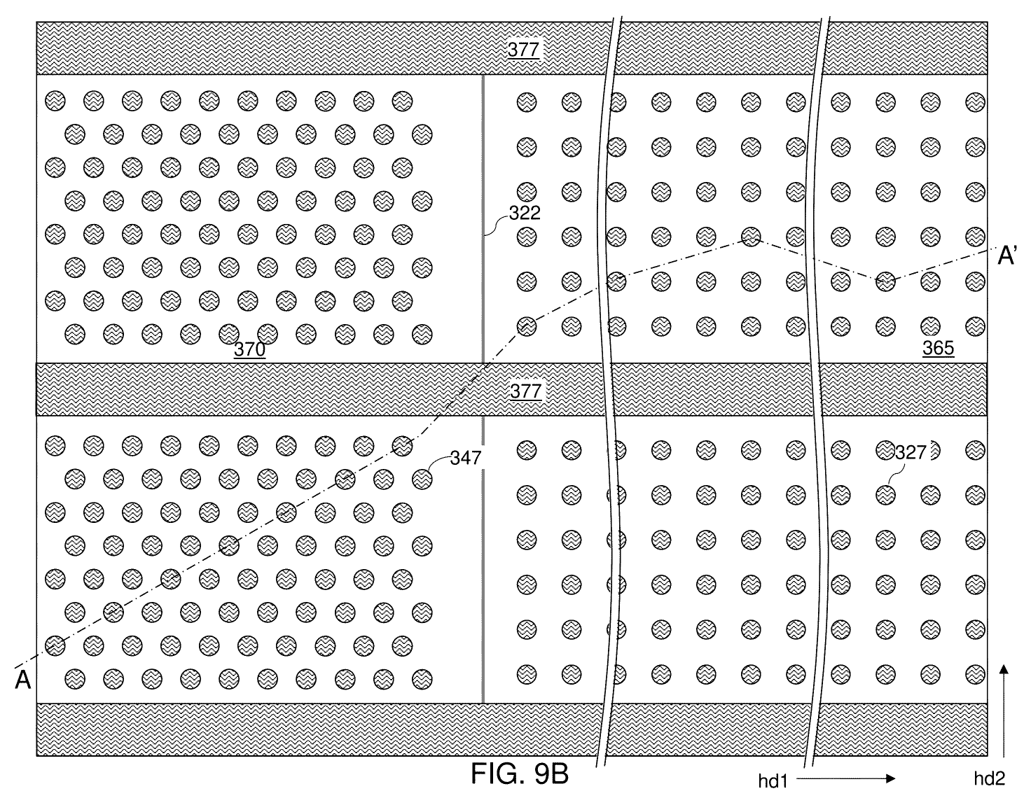

Referring to FIGS. 9A and 9B, the processing steps described with reference to FIGS. 1-3 may optionally be repeated with any needed changes to form a third alternating stack of third insulating layers 332 and third sacrificial material layers 342, third stepped surfaces, a third stepped sacrificial liner 322, a third retro-stepped dielectric material portion 365. The third alternating stack (332, 342) may comprise multiple repetitions of a unit layer stack including a third insulating layer 332 and a third sacrificial material layer 342. The total number of repetitions of the unit layer stack within the third alternating stack (332, 342) may be, for example, in a range from 8 to 1,024, such as from 32 to 256, although lesser and greater number of repetitions may also be employed. The area of the third stepped surfaces may be located in the contact region 300, but may be laterally offset along the first horizontal direction hd1 toward the memory array region 100 relative to the area of the second stepped surfaces. Each third insulating layer 332 may have the same material composition and the same thickness as each first insulating layer 132. Each third sacrificial material layer 342 may have the same material composition and the same thickness as each first sacrificial material layer 142. The third stepped sacrificial liner 322 may have the same material composition and the same thickness as the first stepped sacrificial liner 122. The third retro-stepped dielectric material portion 365 may have the same material composition as the first retro-stepped dielectric material portion 165. A horizontal portion of the third stepped sacrificial liner 322 located over the second retro-stepped dielectric material portion 265 may be removed by photolithographic masking and etching. Alternatively, formation of the third alternating stack (332, 342) may be omitted if the memory device includes only two tiers. An optional additional insulating layer 332T may be deposited over the third retro-stepped dielectric material portion 365, the combination of the third alternating stack (332, 342), and the third stepped sacrificial liner 322.

The processing steps described with reference to FIGS. 4A and 4B can be performed with any needed changes to form various openings through the third alternating stack (332, 342), the third retro-stepped dielectric material portion 365, and the third stepped sacrificial liner 322. The pattern of the openings through the third alternating stack (332, 342), the third retro-stepped dielectric material portion 365, and the third stepped sacrificial liner 322 may be the same as the pattern of the openings through the first alternating stack (132, 142) that are formed at the processing steps described with reference to FIGS. 4A and 4B. The openings that are formed through the third alternating stack (332, 342), the third retro-stepped dielectric material portion 365, and the third stepped sacrificial liner 322 may comprise third-tier memory openings 349 that are formed in the memory array region 100, third-tier support openings 329 that are formed in the contact region 300, and optionally third-tier lateral isolation trenches 379 that laterally extend along the first horizontal direction hd1 across the memory array region 100 and the contact region 300. Each of the third-tier memory openings 349, the third-tier support openings 329, and the third-tier lateral isolation trenches 379 can vertically extend through the third alternating stack (332, 342) and/or the third retro-stepped dielectric material portion 365, and may vertically extend into an upper portion of the second-tier sacrificial opening fill material portions (247, 227, 277).

Subsequently, the processing steps described with reference to FIG. 5 can be performed with any needed changes to form various third-tier sacrificial opening fill material portions (347, 327, 377). The third-tier sacrificial opening fill material portions (347, 327, 377) comprise third-tier sacrificial memory opening fill material portions 347 that are formed in the third-tier memory openings 349, third-tier sacrificial support opening fill material portions 327 that are formed in the third-tier support openings 329, and optional third-tier sacrificial lateral isolation trench fill material portions 377 that are formed in the third-tier lateral isolation trenches 379.

While an embodiment is described in which three alternating stacks are formed over a carrier substrate 9, other embodiments may include any suitable number of alternating stacks of insulating layers (132, 232, 332) and sacrificial material layers (142, 242, 342). In an embodiment in which only one alternating stack is employed, formation of the second alternating stack (232, 242), the second stepped surfaces, the second stepped sacrificial liner 222, and the second retro-stepped dielectric material portion 265 and overlying structures may be omitted. In an embodiment in which only two alternating stacks are employed, formation of the third alternating stack (332, 342), the third stepped surfaces, the third stepped sacrificial liner 322, and the third retro-stepped dielectric material portion 365 may be omitted. Alternatively, at least one additional alternating stack, at least one additional set of stepped surfaces, at least one additional stepped sacrificial liner, and at least one additional retro-stepped dielectric material portion may be employed. Thus, the total number of alternating stacks and stepped sacrificial liners may be adjusted as needed.

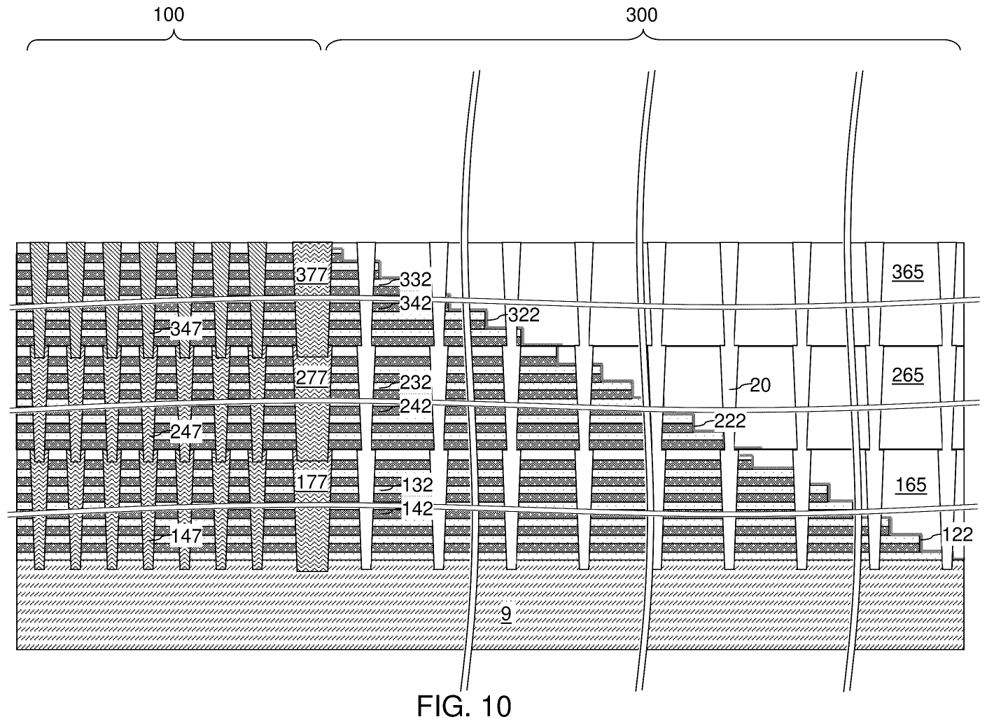

Referring to FIG. 10, a photoresist layer (not shown) can be applied over the alternating stack (332, 342) and the third retro-stepped dielectric material portion 365, and can be lithographically patterned to cover the sacrificial memory opening fill material portions (147, 247, 347) and the sacrificial lateral isolation trench fill material portions (177, 277, 377) without covering the sacrificial support opening fill material portions (127, 227, 327). The sacrificial support opening fill material portions (127, 227, 327) in the contact region 300 can be removed selective to the materials of the alternating stacks {(132, 142), (232, 242), (332, 342)} and the retro-stepped dielectric material portions (165, 265, 365). For example, an etch process or an ashing process may be employed to remove the sacrificial support opening fill material portions (127, 227, 327) in the contact region 300. The photoresist layer can be subsequently removed.

A dielectric fill material, such as silicon oxide, can be deposited in the cavities formed by removal of the sacrificial support opening fill material portions (127, 227, 327) by a conformal deposition process. Excess portions of the dielectric fill material can be removed from above the horizontal plane including the top surface of the third retro-stepped dielectric material portion 365, for example, by a recess etch process. Each portion of the dielectric fill material that fills a respective cavity constitutes a support pillar structure 20, which can be employed to provide structural support to the insulating layers (132, 232, 332) and the retro-stepped dielectric material portions (165, 265, 365) during subsequent replacement of the sacrificial material layers (142, 242, 342) with electrically conductive layers.

Each support pillar structure 20 vertically extends at least from a horizontal plane including the bottom surface of the first alternating stack (132, 142), and at least to a horizontal plane including the top surface of the third alternating stack (332, 342). In one embodiment, each support pillar structure 20 consists essentially of at least one dielectric fill material. In one embodiment, each support pillar structure 20 comprises a first dielectric sidewall that vertically extends through the first alternating stack (132, 142); a second dielectric sidewall that vertically extends through the second alternating stack (232, 242); and a third dielectric sidewall that vertically extends through the third alternating stack (332, 342). Alternatively, the steps described above with respect to FIG. 10 may be omitted and the support pillar structures 20 may have the same structure as the memory opening fill structures described below.

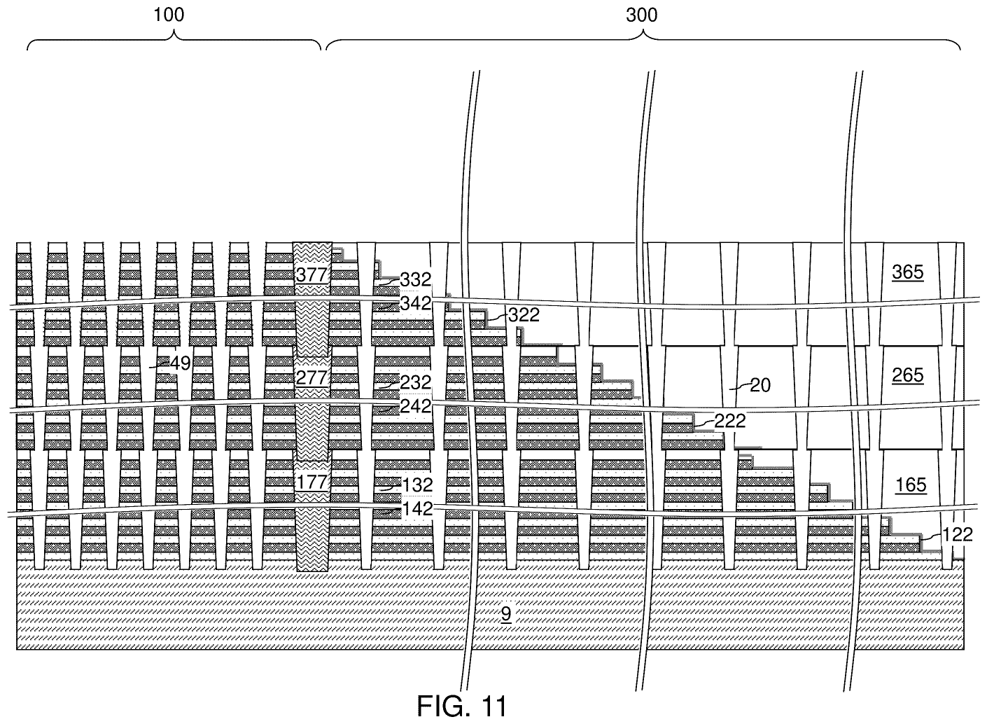

Referring to FIG. 11, a photoresist layer (not shown) can be applied over the third alternating stack (332, 342) and the third retro-stepped dielectric material portion 365, and can be lithographically patterned to cover the sacrificial lateral isolation trench fill material portions (177, 277, 377) without covering the sacrificial memory opening fill material portions (147, 247, 347). The sacrificial memory opening fill material portions (147, 247, 347) in the memory array region 100 can be removed selective to the materials of the alternating stacks {(132, 142), (232, 242), (332, 342)} and the retro-stepped dielectric material portions (165, 265, 365) to form inter-tier memory openings 49, which are also referred to as memory openings 49. For example, an etch process or an ashing process may be employed to remove the sacrificial memory opening fill material portions (147, 247, 347) in the memory array region 100. The photoresist layer can be subsequently removed.

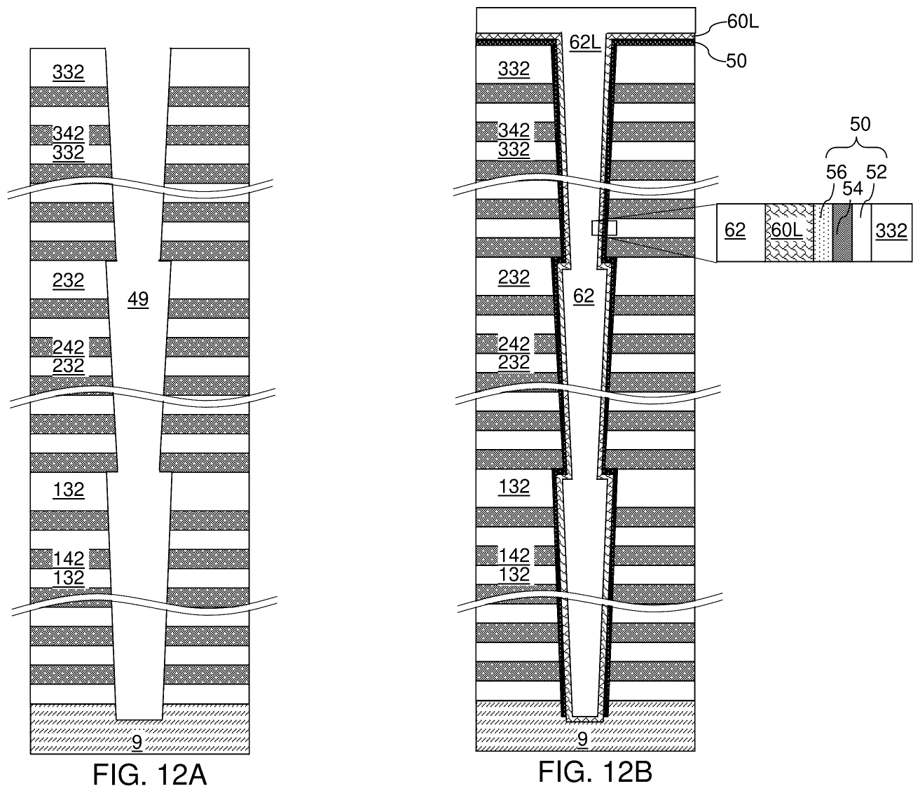

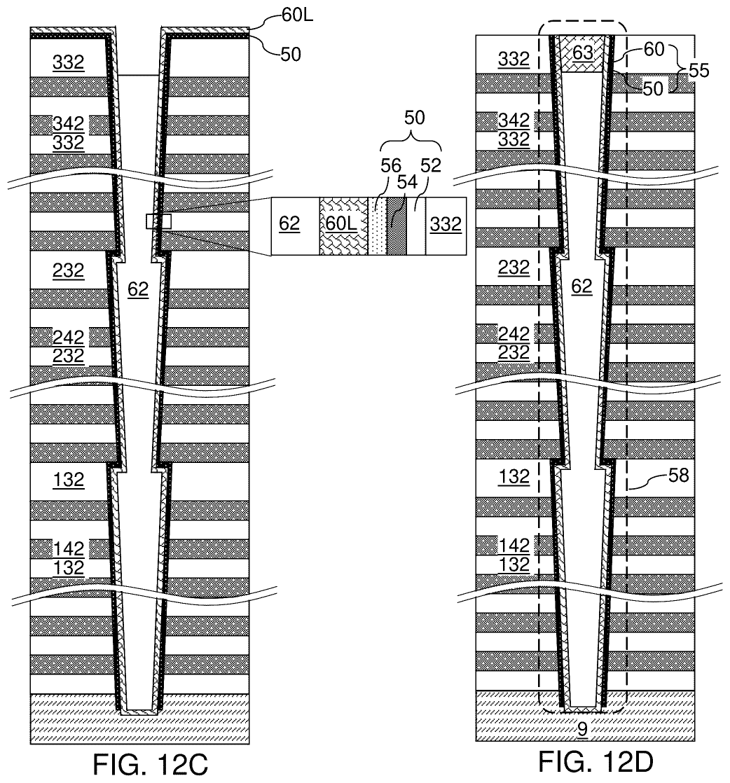

FIGS. 12A-12D are sequential vertical cross-sectional views of an inter-tier memory opening 49 (i.e., a memory opening 49) during formation of a memory opening fill structure 58 according to an embodiments of the present disclosure.

Referring to FIG. 12A, a memory opening 49 is illustrated after the processing steps of FIG. 11.

Referring to FIG. 12B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material (e.g., silicon oxide) can be deposited in remaining volumes of the memory openings 49 and over the alternating stack {(132, 232, 332), (142, 242, 342)}.

Referring to FIG. 12C, the dielectric core layer 62L can be vertically recessed such that each remaining portion of the dielectric core layer 62L has a top surface at, or about, the horizontal plane including the bottom surface of the topmost third insulating layer 332. Each remaining portion of the dielectric core layer 62L constitutes a dielectric core 62.

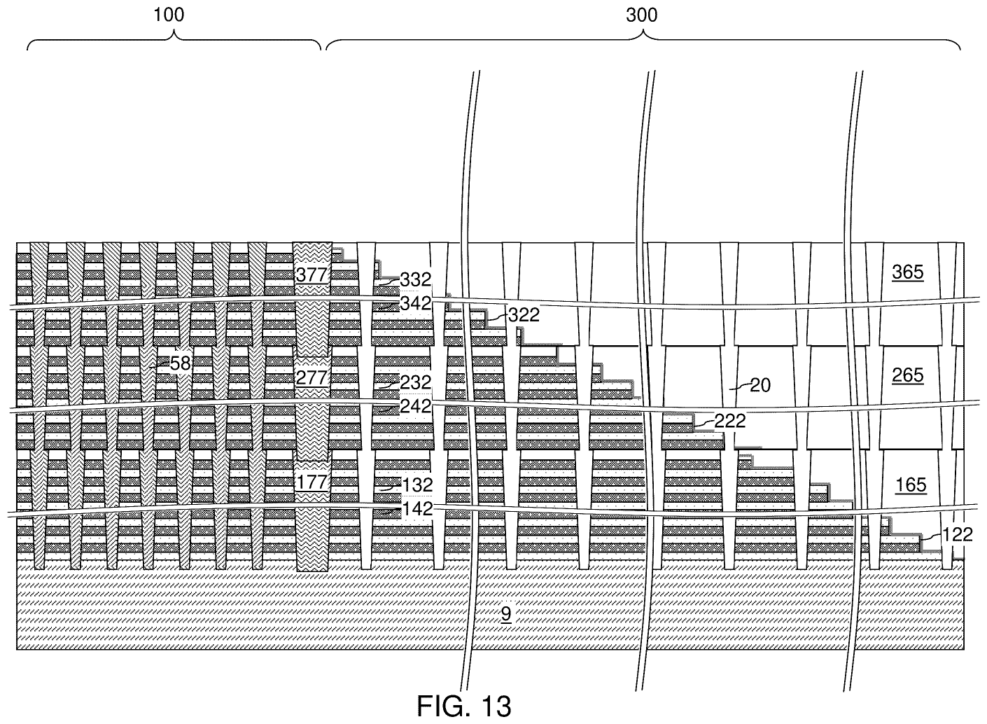

Referring to FIGS. 12D and 13, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost third insulating layer 332, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers (142, 242, 342).

In an alternative embodiment, the support pillar structures 20 may have the same composition and structure as the memory opening fill structures 58. In this embodiment, the memory openings and the support openings filled with the respective layers (52, 54, 56, 60, 62 and 63) during the same deposition steps.

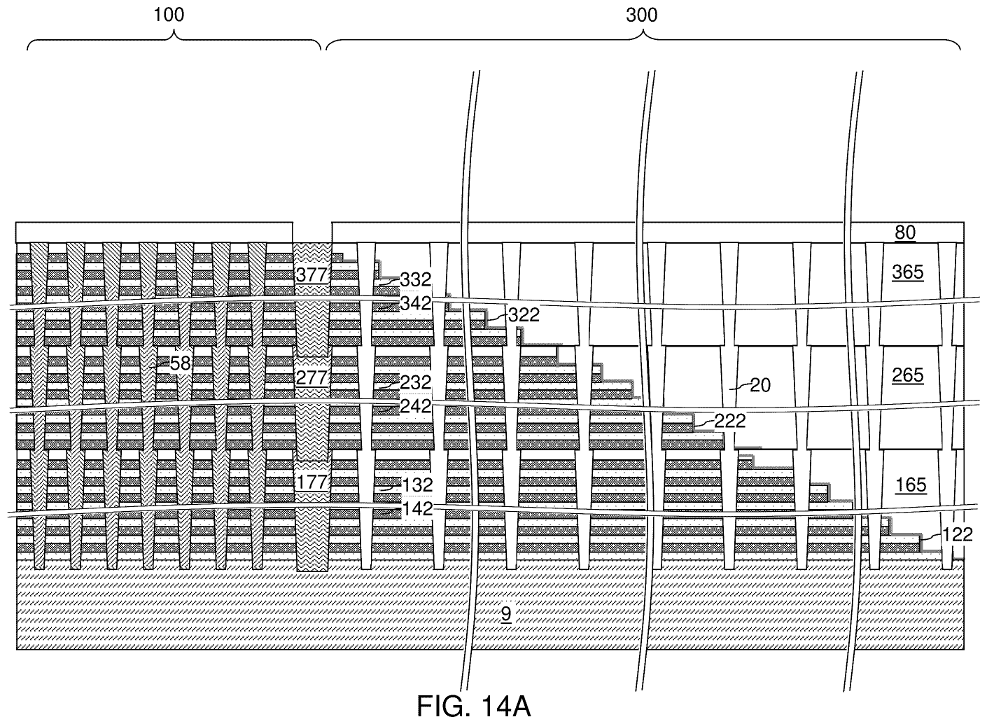

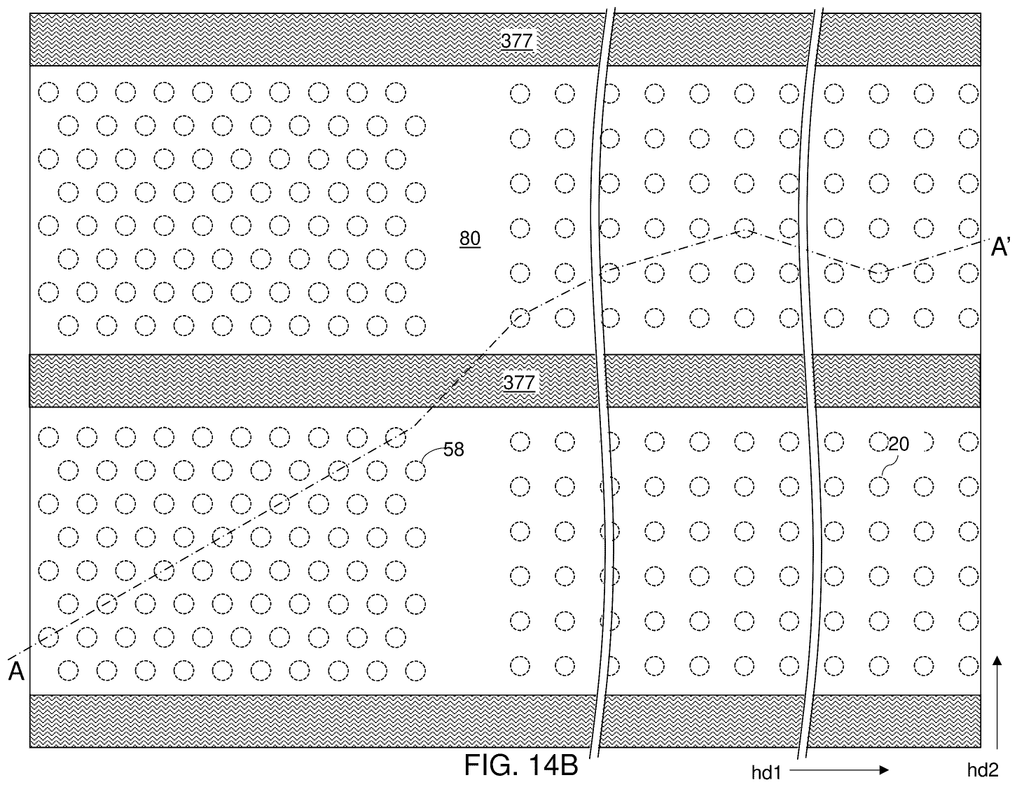

Referring to FIGS. 14A and 14B, a contact-level dielectric layer 80 can be deposited over the third alternating stack (332, 342) and the third retro-stepped dielectric material portion 365. The contact-level dielectric layer 80 comprises a dielectric material such as silicon oxide, and may have a thickness in a range from 100 nm to 800 nm, although lesser and greater thicknesses may also be employed.

A photoresist layer can be applied over the contact-level dielectric layer 80, and can be lithographically patterned to form strip-shaped openings that overlie the sacrificial lateral isolation trench fill material portions (177, 277, 377). An anisotropic etch process can be performed to form slit-shaped openings through the contact-level dielectric layer 80 over the areas of the sacrificial lateral isolation trench fill material portions (177, 277, 377). The slit-shaped openings are also referred to as contact-level trenches. The photoresist layer can be subsequently removed, for example, by ashing.

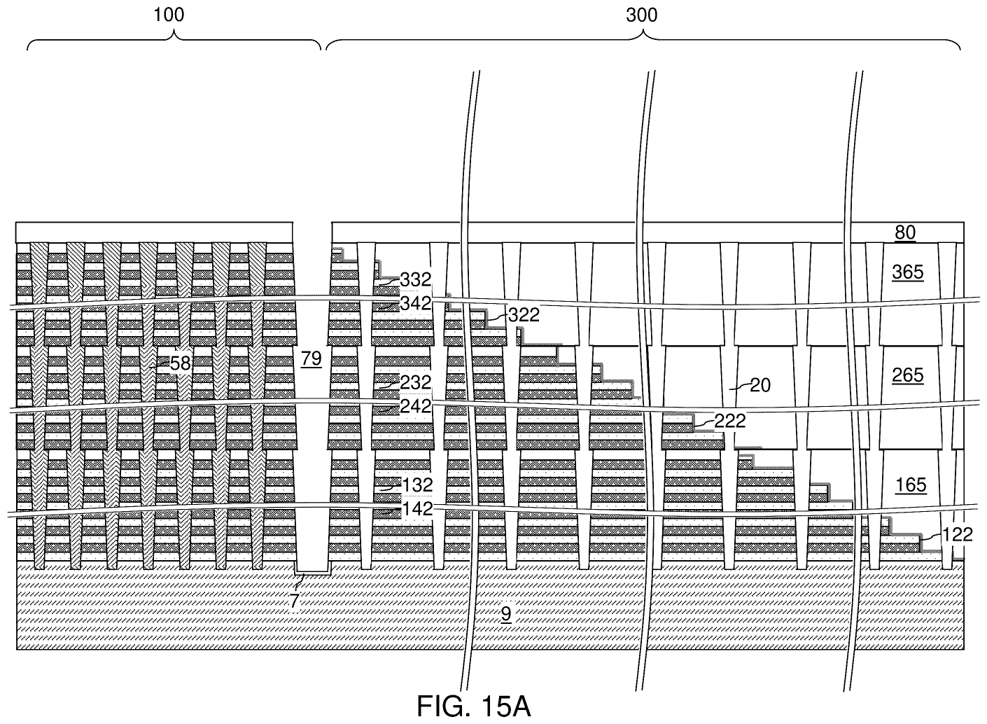

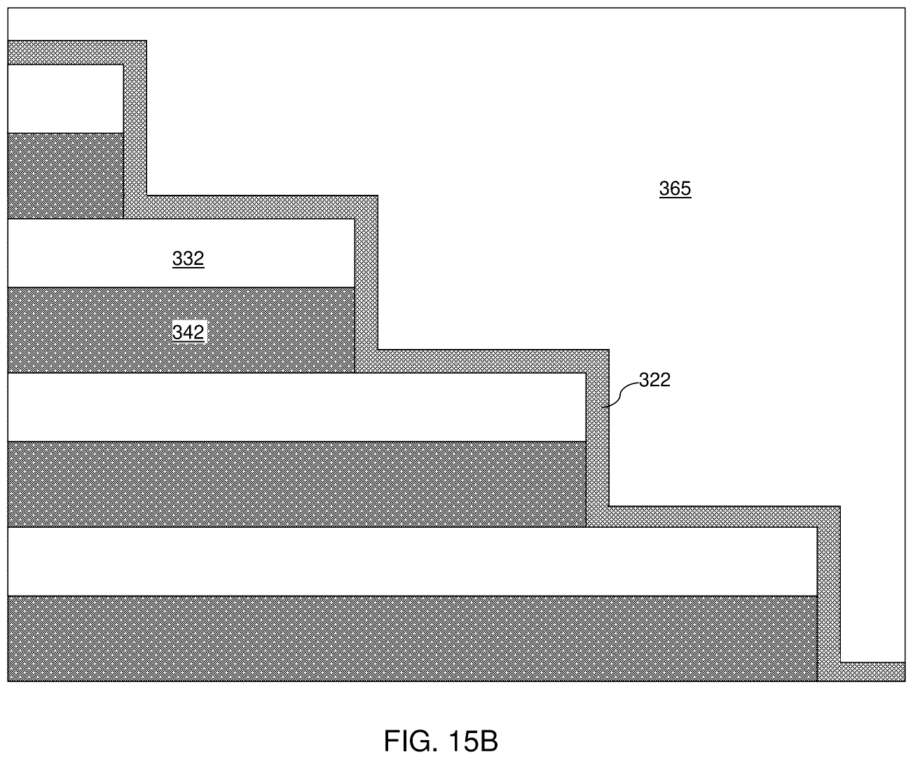

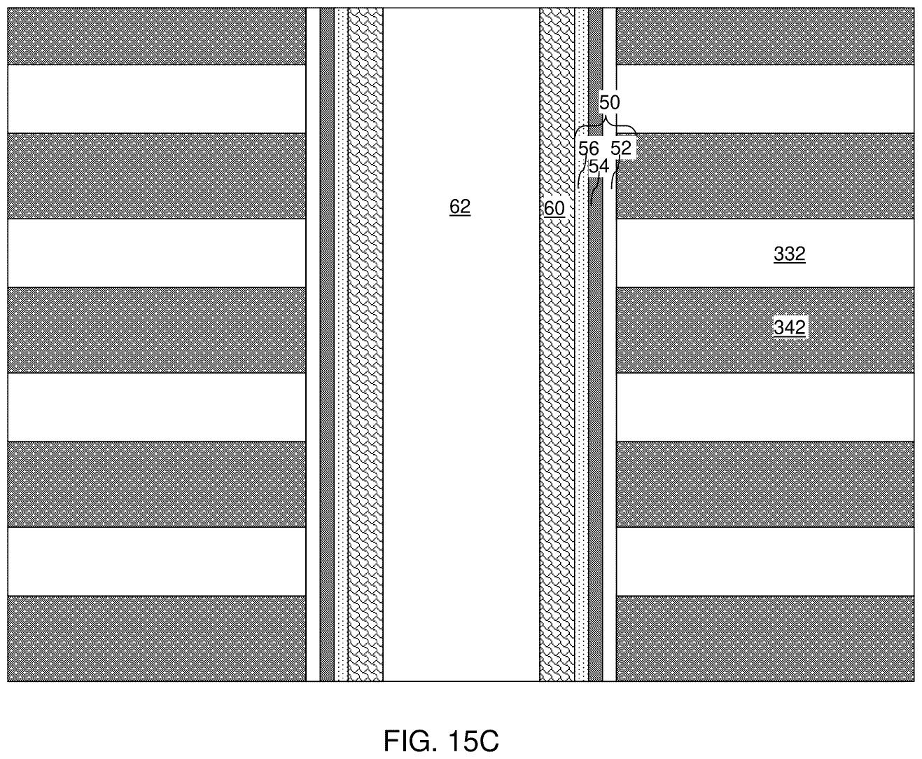

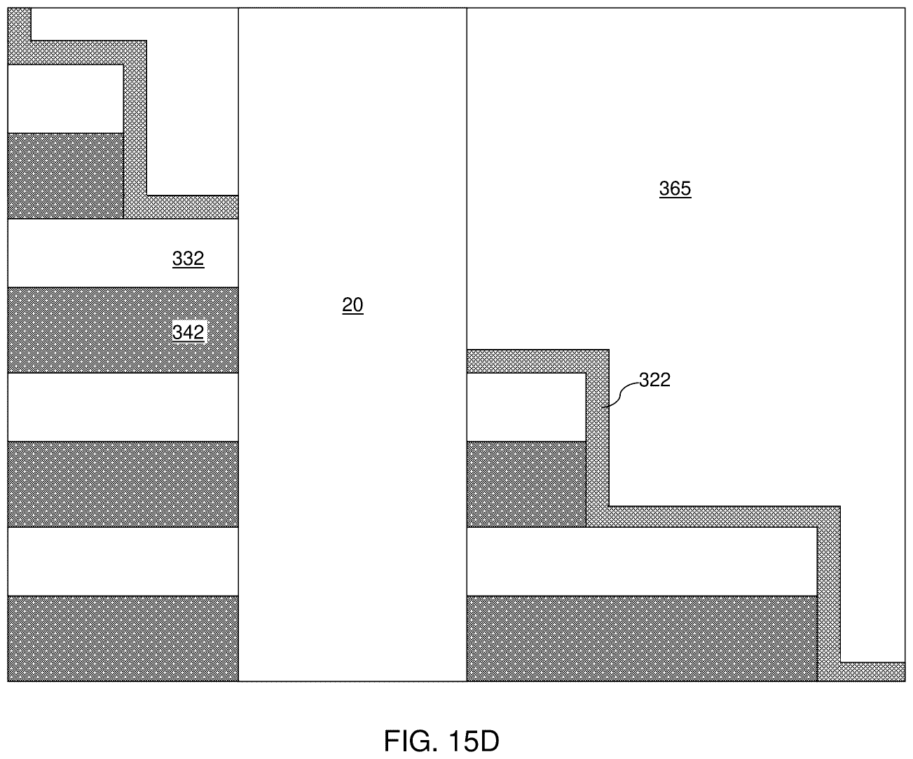

Referring to FIGS. 15A-15D, the sacrificial lateral isolation trench fill material portions (177, 277, 377) can be removed selective to the materials of the alternating stacks {(132, 142), (232, 242), (332, 342)} and the retro-stepped dielectric material portions (165, 265, 365) to form lateral isolation trenches 79. For example, an etch process or an ashing process may be employed to remove the sacrificial lateral isolation trench fill material portions (177, 277, 377).

In an alternative embodiment, the first-tier lateral isolation trenches 179, the second-tier lateral isolation trenches 279, the third-tier lateral isolation trenches 379, and the sacrificial lateral isolation trench fill material portions (177, 277, 377) may not be formed during the processing steps of FIGS. 1-13. In this case, the lateral isolation trenches 79 may be formed during a separate masking and etching step that is performed after formation of the contact-level dielectric layer 80. Generally, lateral isolation trenches 79 can be formed through an alternating stack {(132, 232, 332), (146, 246, 346)} incrementally during formation of each tier or at once after formation of all tiers.

An oxidation process can be performed to covert physically exposed surface portions of the carrier substrate 9 into dielectric semiconductor oxide liners 7. For example, if the carrier substrate 9 comprises a silicon substrate, the dielectric semiconductor oxide liners 7 may comprise silicon oxide liners.

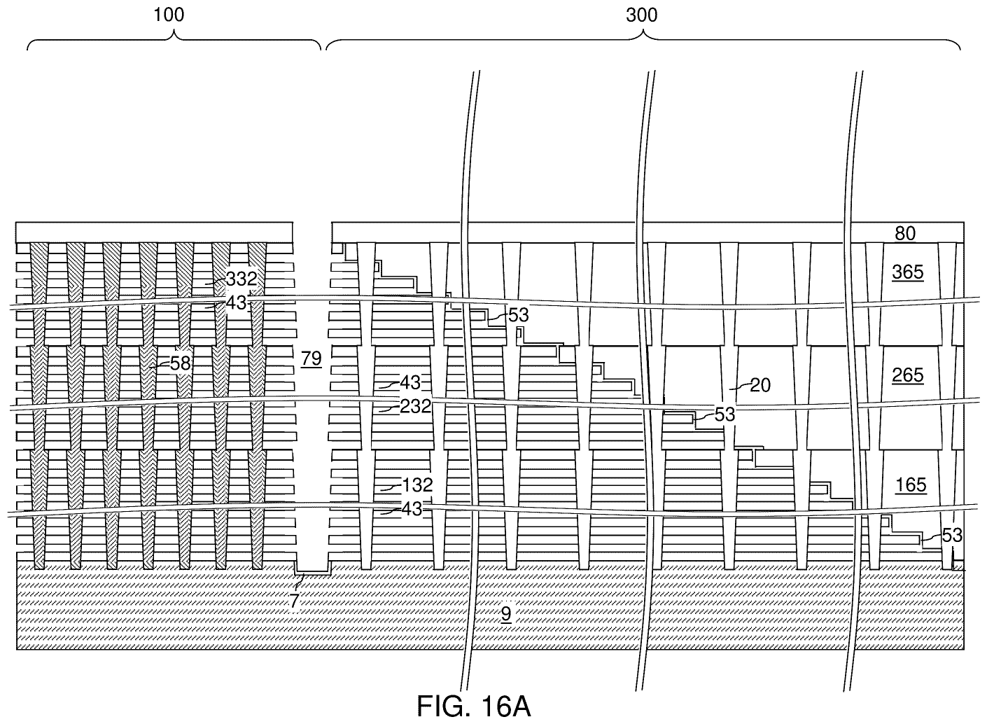

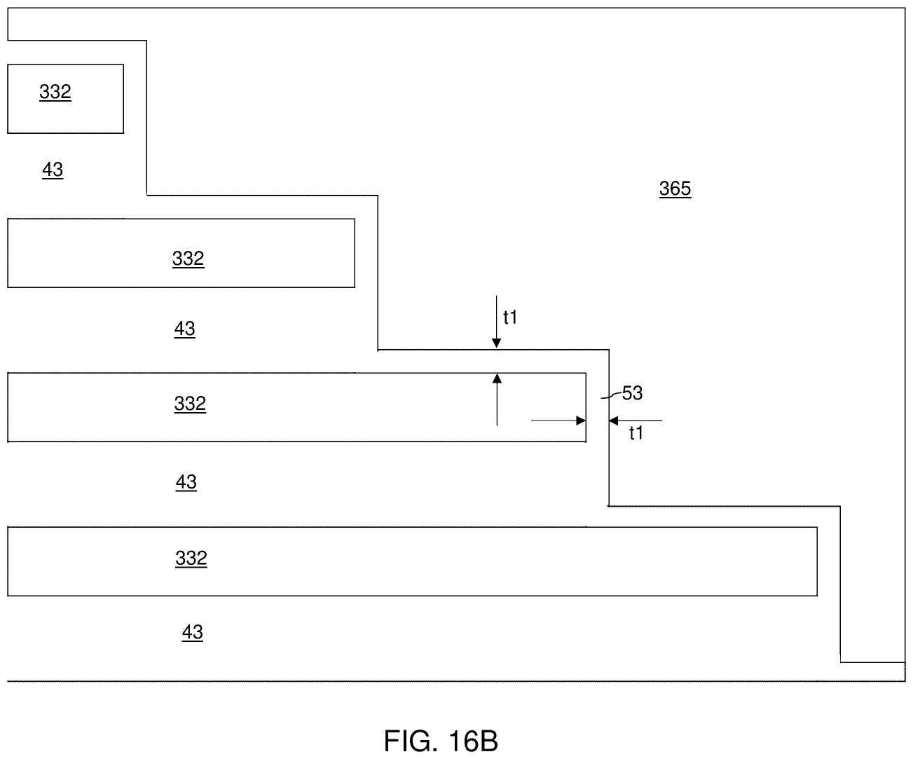

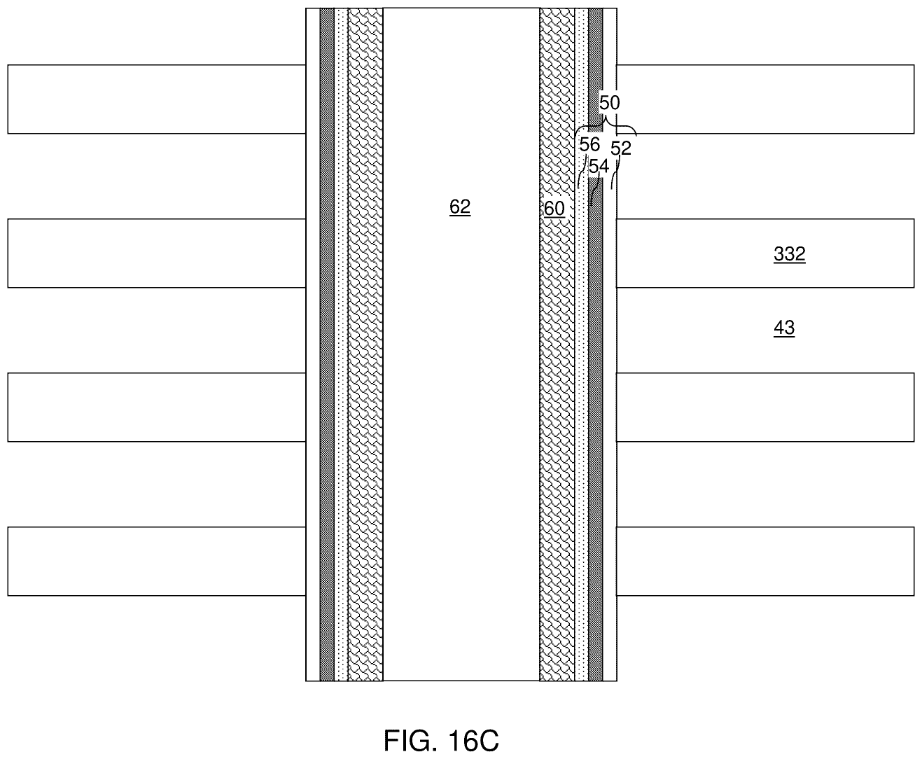

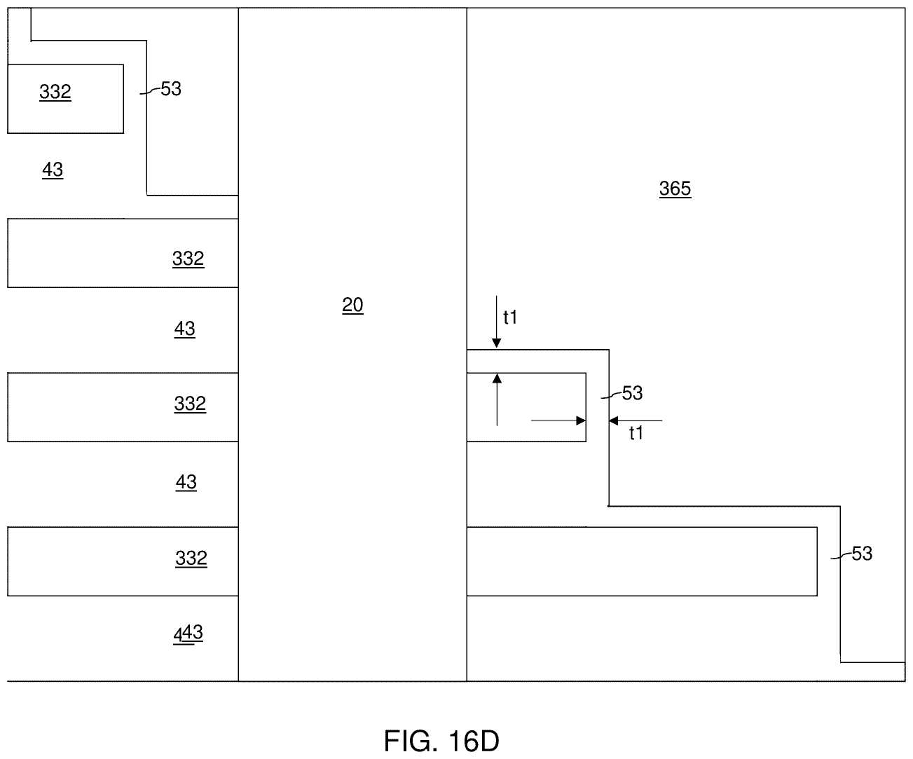

Referring to FIGS. 16A-16D, an isotropic etch process can be performed to remove the sacrificial material layers (142, 242, 342) and the stepped sacrificial liners (122, 222, 322) selective to the insulating layers (132, 232, 332), the contact-level dielectric layer 80, the memory opening fill structures 58, the support pillar structures 20, and the carrier substrate 9. The isotropic etch process employs an isotropic etchant that etches materials of the sacrificial material layers (142, 242, 342) and the stepped sacrificial liners (122, 222, 322) selective to the material of the insulating layers (132, 232, 332). In an illustrative example, the insulating layers (132, 232, 332) may comprise silicon oxide, and the sacrificial material layers (142, 242, 342) and the stepped sacrificial liners (122, 222, 322) may comprise silicon nitride. In this case, the isotropic etch process that removes the sacrificial material layers (142, 242, 342) and the stepped sacrificial liners (122, 222, 322) may comprise a wet etch process employing hot phosphoric acid. The duration of the isotropic etch process can be selected such that the lateral etch distance of the isotropic etch process for the sacrificial material layers (142, 242, 342) and the stepped sacrificial liners (122, 222, 322) is greater than one half of the lateral spacing along neighboring pairs of lateral isolation trenches 79 along the second horizontal direction hd2.

A continuous void (43, 53) including laterally-extending cavities 43 and a staircase-shaped cavity 53 can be formed between each neighboring pair of lateral isolation trenches 79. The laterally-extending cavities 43 can be formed in volumes from which the sacrificial material layers (142, 242, 342) are removed. Sidewall surface segments of the memory opening fill structures 58 can be physically exposed to the laterally-extending cavities 43. The staircase-shaped cavity 53 is formed in volumes from which the materials of the first stepped sacrificial liner 122, the second stepped sacrificial liner 222, and the third stepped sacrificial liner 322 are removed. The staircase-shaped cavity 53 may vertically extend from the top surface of the carrier substrate 9 to the bottom surface of the contact-level dielectric layer 80. In one embodiment, the staircase-shaped cavity 53 comprises horizontally-extending portions and vertically-extending portions. In one embodiment, if the first stepped sacrificial liner 122, the second stepped sacrificial liner 222, and the third stepped sacrificial liner 322 have a same thickness, which is herein referred to as a first uniform thickness t1, the horizontally-extending portions and the vertically-extending portions of the staircase-shaped cavity 53 may have the first uniform thickness t1.

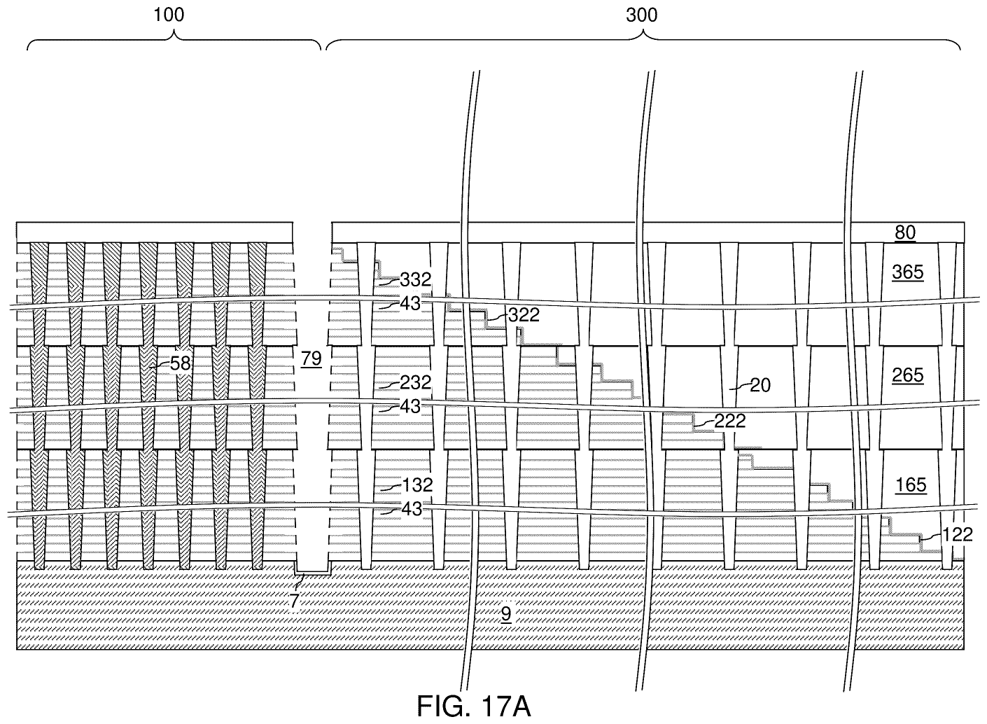

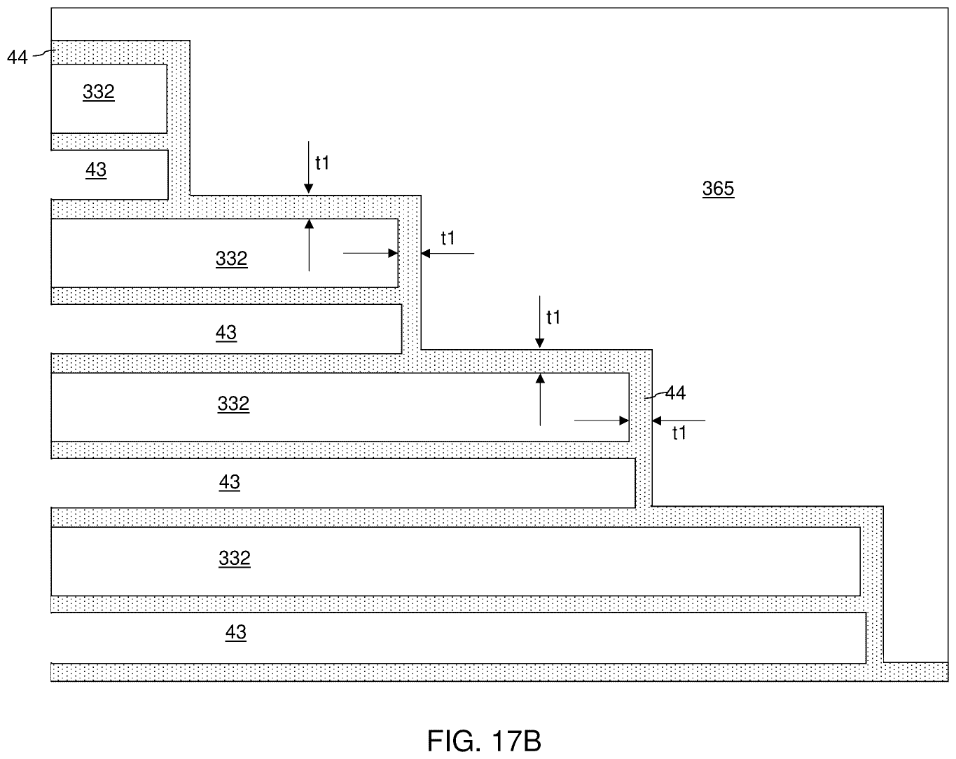

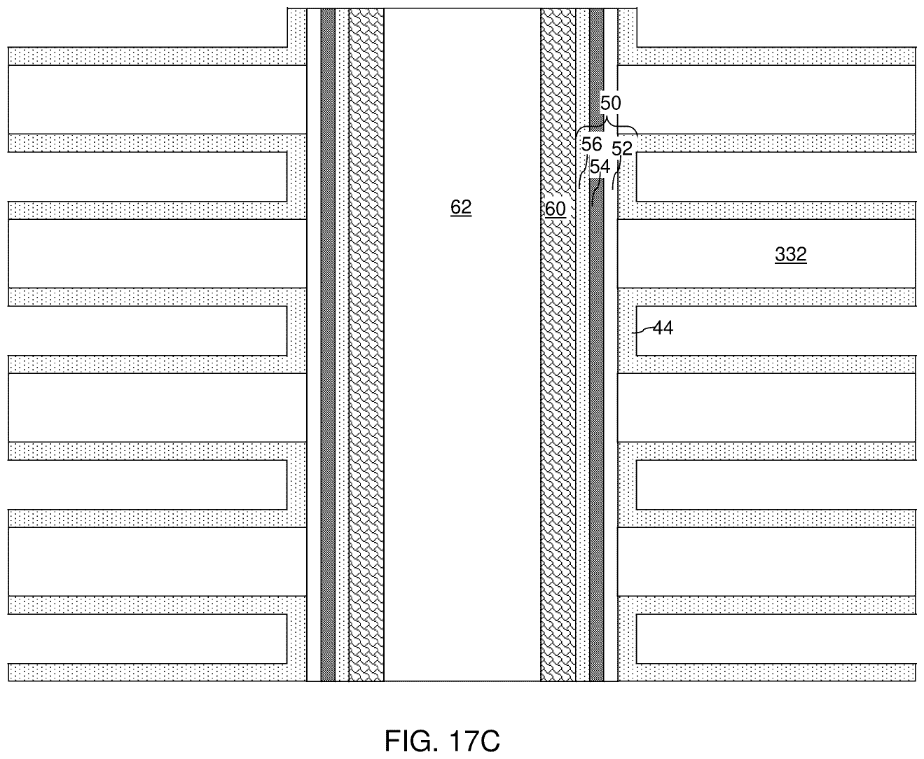

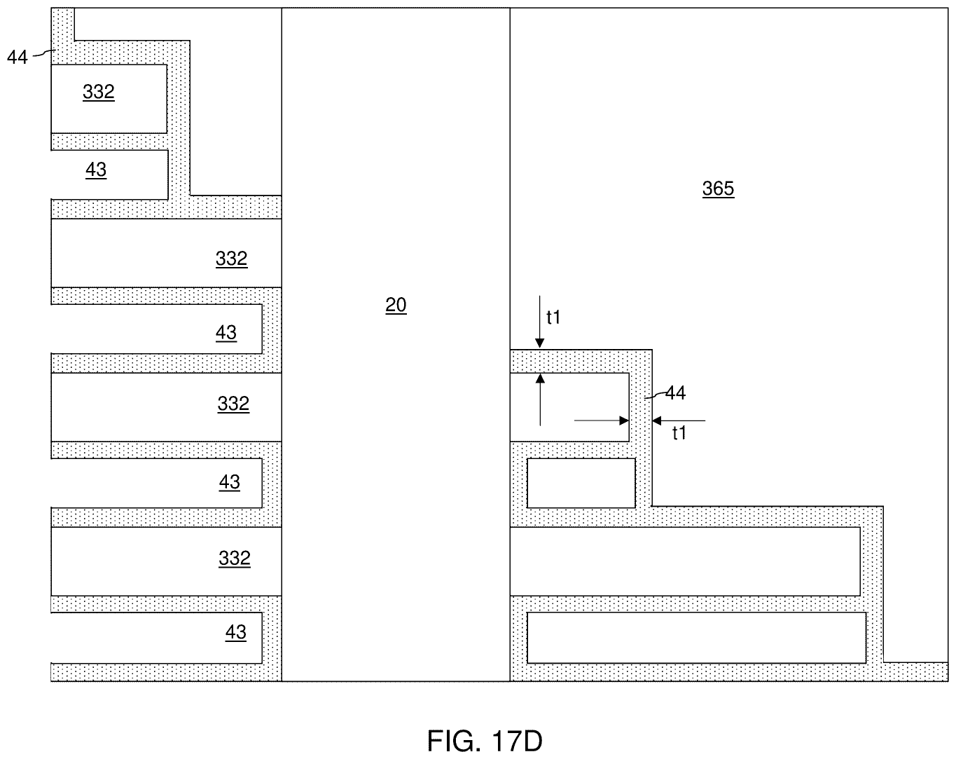

Referring to FIGS. 17A-17D, a dielectric liner material can be conformally deposited in the continuous voids (43, 53) to form a continuous etch-stop and blocking dielectric layer 44. The dielectric liner material comprise a dielectric material that can function as a blocking dielectric material in a NAND memory device and as an etch-stop material during subsequent formation of layer contact via material. For example, the dielectric liner material may comprise a dielectric metal oxide material, such as aluminum oxide or a transition metal oxide (such as zirconium oxide, yttrium oxide, lanthanum oxide, niobium oxide, tantalum oxide, etc.). The dielectric liner material can be conformally deposited within the continuous voids (43, 53) by performing a conformal deposition process, which may comprise an atomic layer deposition (ALD) process or a chemical vapor deposition (CVD) process. The dielectric liner material can be conformally deposited in the staircase-shaped cavity 53 and in peripheral portions of the laterally-extending cavities 43.

The thickness of the deposited dielectric liner material in the peripheral portions of the laterally-extending cavities 43 is greater than one half of the first uniform thickness t1, which is the thickness of the stepped sacrificial liners (122, 222, 322) prior to formation of the staircase-shaped cavities 53. The horizontally-extending portions of the staircase-shaped cavities 53 and vertically-extending portions of the staircase-shaped cavities 53 that are located adjacent to insulating layers (132, 232, 332) are completely filled by the continuous etch-stop and blocking dielectric layers 44. Each continuous etch-stop and blocking dielectric layer 44 may continuously extend laterally between a neighboring pair of lateral isolation trenches 79, and may continuously extend vertically between a top surface of the carrier substrate 9 to a bottom surface of the contact-level dielectric layer 80. The thickness of a portions of the continuous etch-stop and blocking dielectric layer 44 that do not fill gaps between insulating layers (132, 232, 332) and retro-stepped dielectric material portions (165, 265, 365) is greater than one half of the first uniform thickness t1, and is less than one half of the thickness of each sacrificial material layer (142, 242, 342) prior to formation of the laterally-extending cavities 43.

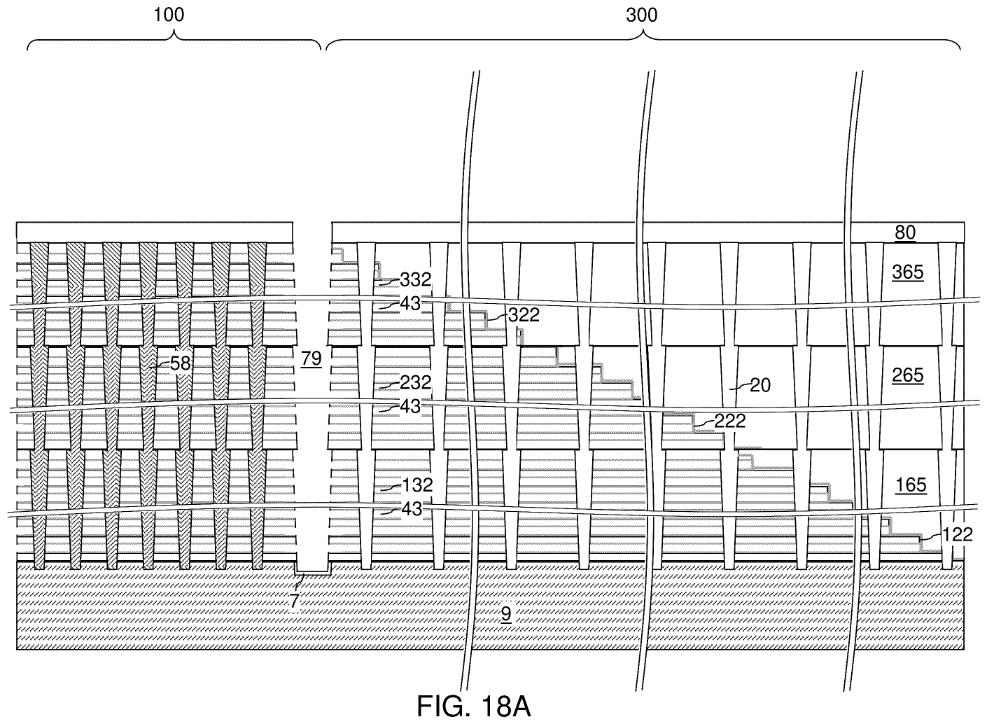

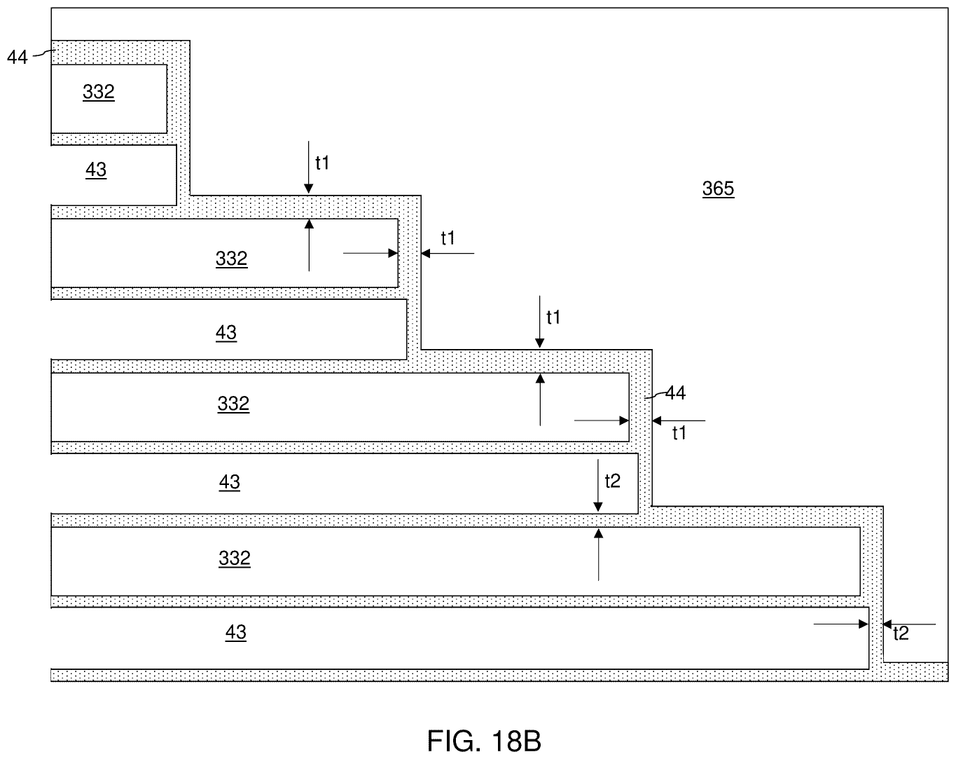

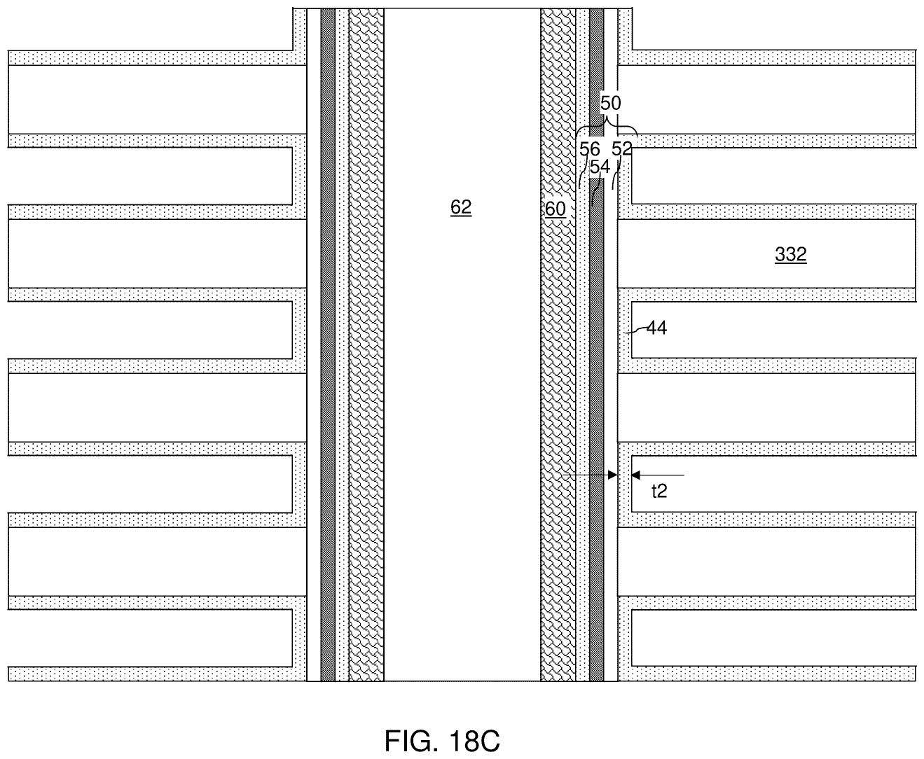

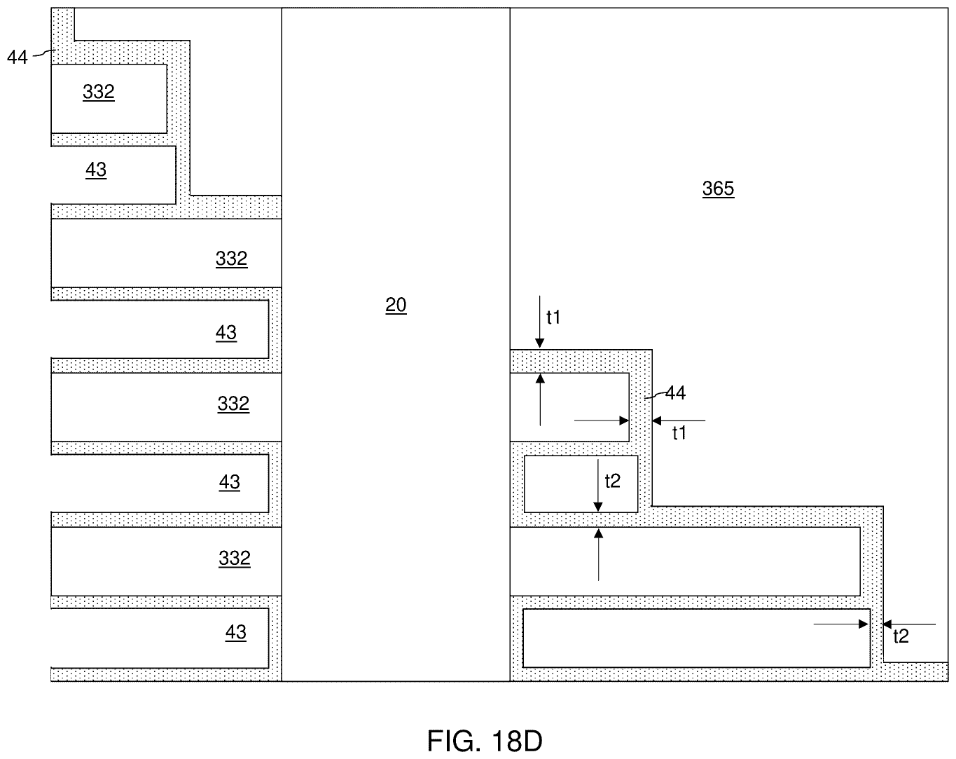

Referring to FIGS. 18A-18D, an optional isotropic etch-back process may be performed to isotropically thin portions of each continuous etch-stop and blocking dielectric layer 44 that are exposed to the laterally-extending cavities 43. The physically exposed portions of each continuous etch-stop and blocking dielectric layer 44 can be thinned to a target thickness, which is herein referred to as a second uniform thickness t2. The second uniform thickness t2 can be selected to provide a desired blocking dielectric thickness in NAND memory cells to be subsequently formed. In this case, each NAND memory cell comprises a portion of a vertical semiconductor channel 60, a cylindrical portion of a memory film 50 located at a level of a laterally-extending cavity 43, a cylindrical remaining portion of a continuous etch-stop and blocking dielectric layer 44 that laterally surrounds the cylindrical portion of the memory film 50, and an electrically conductive layer to be subsequently formed on the cylindrical remaining portion of a continuous etch-stop and blocking dielectric layer 44. In an illustrative example, the second uniform thickness t2 may be in a range from 2 nm to 8 nm, such as from 3 nm to 7 nm, although lesser and greater thicknesses may also be employed. Generally, the second uniform thickness t2 may be in a range from 20% of the first uniform thickness to 90%, of the first uniform thickness t1. The recess etch distance of the isotropic etch-back process can be less than the thickness of the deposited dielectric liner material in the peripheral portions of the laterally-extending cavities 43. Remaining portions of the deposited dielectric liner material between neighboring pairs of lateral isolation trenches 79 comprise the continuous etch-stop and blocking dielectric layers 44.

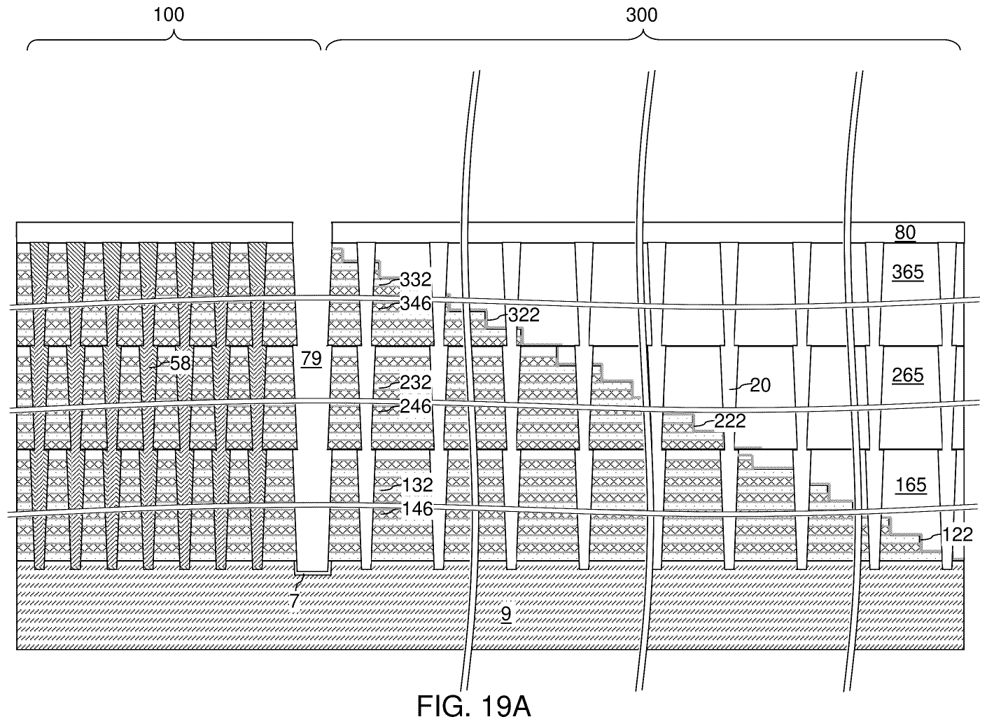

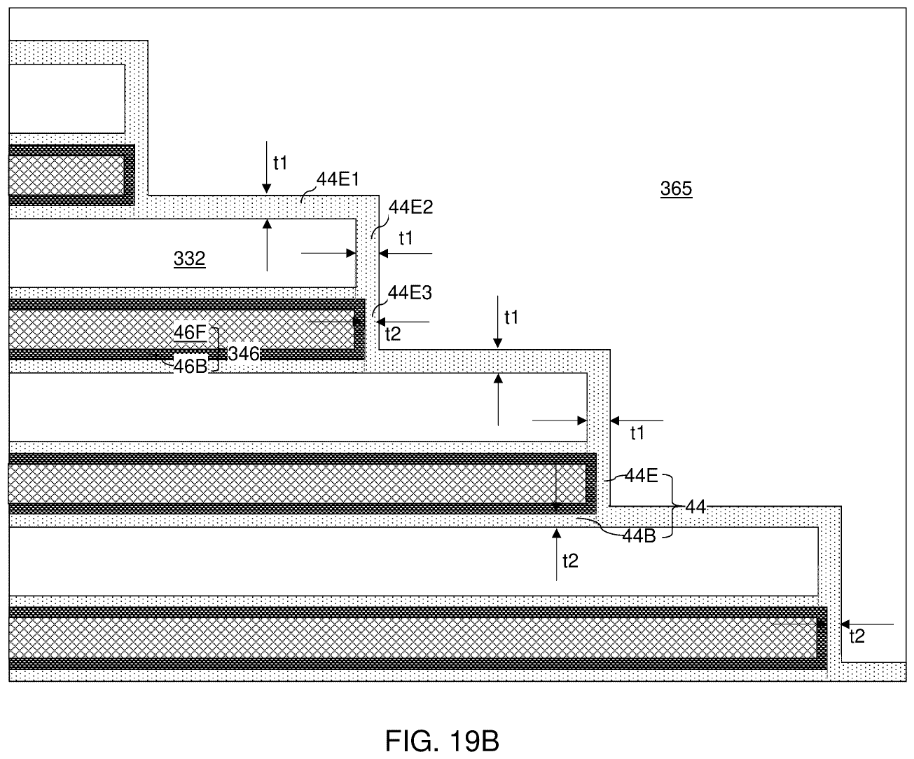

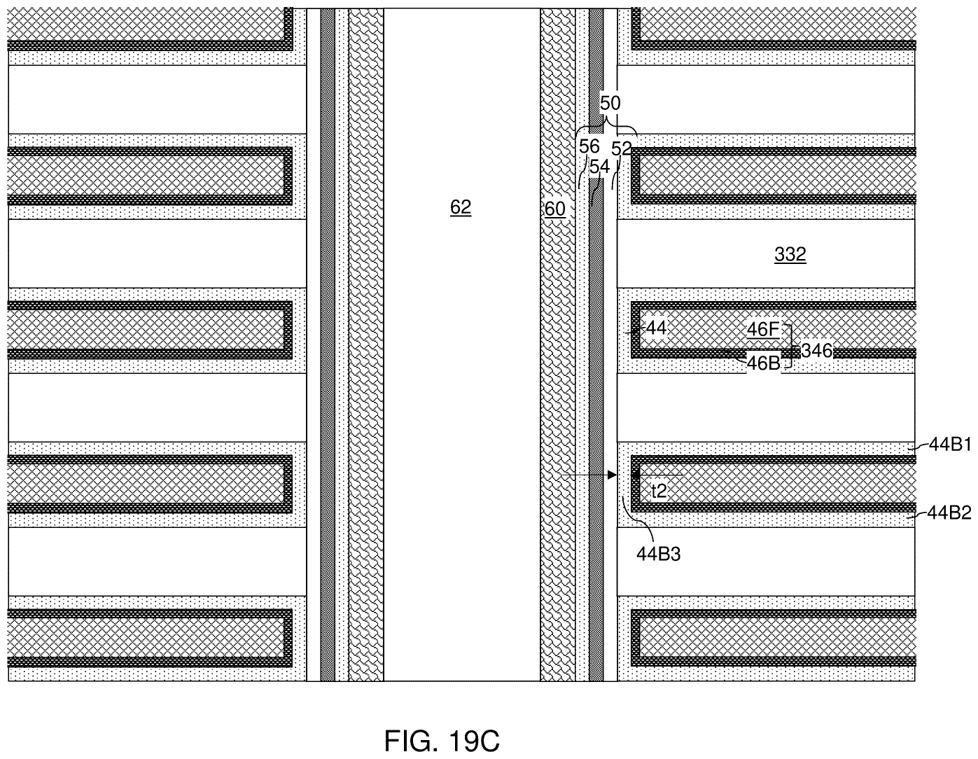

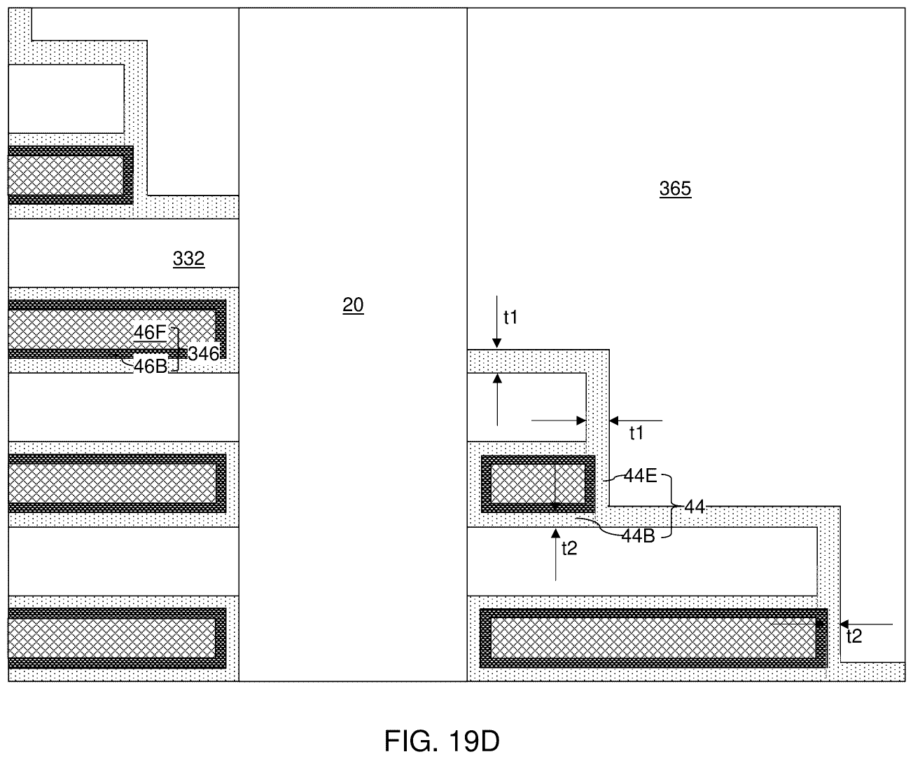

Referring to FIGS. 19A-19D, at least one conductive material, such as at least one metallic material, can be conformally deposited in remaining unfilled volumes of the laterally-extending cavities 43. The at least one conductive material may comprise, for example, a combination of a metallic barrier material and a metallic fill material. The metallic barrier material may comprise, for example, TiN, TaN, WN, MoN, TiC, TaC, WC, or a combination thereof. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the laterally-extending cavities 43 constitutes an electrically conductive layer (146, 246, 346).

The electrically conductive layers (146, 246, 346) comprise first electrically conductive layers 146 that are interlaced with the first insulating layers 132, second electrically conductive layers 246 that are interlaced with the second insulating layers 232, and third electrically conductive layers 346 that are interlaced with the third insulating layers 332. An alternating stack of insulating layers (132, 232, 332) and electrically conductive layers (146, 246, 346) can be formed between each neighboring pair of lateral isolation trenches 79 over the carrier substrate 9. A plurality of alternating stacks of insulating layers (132, 232, 332) and electrically conductive layers (146, 246, 346) can be laterally spaced apart among one another by the lateral isolation trenches 79.

The continuous etch-stop and blocking dielectric layer 44 includes blocking dielectric layer portions 44B and an etch-stop dielectric layer portion 44E. The etch-stop dielectric layer portion 44E may continuously extend from a bottommost insulating layer of the insulating layers (132, 232, 332) to a topmost insulating layer of the insulating layers (132, 232, 332) with a staircase-shaped vertical cross-sectional profile. Each of the blocking dielectric layer portions 44B is formed in a peripheral region of a respective one of the laterally-extending cavities 43.

In one embodiment shown in FIG. 19C, each of the blocking dielectric layer portions 44B comprises a respective pair of horizontally-extending blocking dielectric layer segments (44B1, 44B2) joined by a respective set of tubular blocking dielectric layer segments 44B3 that laterally surround a respective one of the memory opening fill structures 58. In one embodiment shown in FIG. 19C, each of the electrically conductive layers (146, 246, 346) comprises a planar top surface an entirety of which is contacted by an upper horizontally-extending blocking dielectric layer segment 44B1 within a respective blocking dielectric layer portion 44B, and a planar bottom surface an entirety of which is contacted by a lower horizontally-extending blocking dielectric layer segment 44B2 within the respective blocking dielectric layer portion 44B.

In one embodiment shown in FIG. 19B, all horizontally-extending segments 44E1 of the etch-stop dielectric layer portion 44E have a first uniform thickness t1, and all horizontally-extending segments (44B1, 44B2) and all vertically-extending segments 44B3 of the blocking dielectric layer portions 44B have a second uniform thickness t2. The first uniform thickness t1 is greater than the second uniform thickness t2. In one embodiment, the first uniform thickness t1 at least 10% greater and not more than 600% greater than the second uniform thickness t2. In one embodiment shown in FIG. 19B, first vertically-extending segments 44E2 of the etch-stop dielectric layer portion 44E in contact with a sidewall of a respective insulating layer (132, 232, 332) have the first uniform thickness t1, and second vertically-extending segments 44E3 of the etch-stop dielectric layer portion 44E in contact with a sidewall of a respective electrically conductive layer (146, 246, 346) have the second uniform thickness t2.

In one embodiment shown in FIG. 19B, each neighboring pair of horizontally-extending segments 44E1 of the etch-stop dielectric layer portion 44E is joined to each other by a combination of a respective one of the first vertically-extending segments 44E2 of the etch-stop dielectric layer portion 44E and a respective one of the second vertically-extending segments 44E3 of the etch-stop dielectric layer portion 44E. In one embodiment shown in FIG. 19B, each of the first vertically-extending segments 44E2 of the etch-stop dielectric layer portion 44E contacts a sidewall of a respective insulating layer (132, 232, 332) within the alternating stack {(132, 232, 332), (146, 246, 346)}, and each of the second vertically-extending segments 44E3 of the etch-stop dielectric layer portion 44E contacts a sidewall of a respective electrically conductive layer (146, 246, 346) within the alternating stack {(132, 232, 332), (146, 246, 346)}.

In one embodiment, each of the electrically conductive layers (146, 246, 346) comprises a respective metallic barrier liner 46B in contact with a respective one of the blocking dielectric layer portions 44B and in contact with a respective vertically-extending segment 44E3 of the etch-stop dielectric layer portion 44E, and a respective metallic fill material portion 46F that is embedded within the respective metallic barrier liner 46B and spaced from the continuous etch-stop and blocking dielectric layer 44 by the respective metallic barrier liner 46B.

In one embodiment shown in FIG. 19B, a retro-stepped dielectric material portion (165, 265, or 365) comprising a stepped bottom surface that overlies and is in contact with the etch-stop dielectric layer portion 44E. In one embodiment, each insulating layer (132, 232, 332) is laterally spaced from the retro-stepped dielectric material portion (165, 265, or 365) by a respective first vertically-extending segment 44E2 of the etch-stop dielectric layer portion 44E having a first uniform thickness t1, and each electrically conductive layer (146, 246, 346) is laterally spaced from the retro-stepped dielectric material portion (165, 265, or 365) by a respective second vertically-extending segment 44E3 of the etch-stop dielectric layer portion 44E having a second uniform thickness t2 that is less than the first uniform thickness t1. In one embodiment shown in FIG. 19B, each insulating layer (132, 232, 332) is vertically spaced from a respective overlying portion of the retro-stepped dielectric material portion (165, 265, or 365) by a respective horizontally-extending segment 44E1 of the etch-stop dielectric layer portion 44E having the first uniform thickness t1. In one embodiments, horizontally-extending segments 44E1 of the etch-stop dielectric layer portion 44E have a first uniform thickness t1 that is less than a vertical spacing between neighboring pairs of insulating layers (132, 232, 332) within the alternating stack {(132, 232, 332), (146, 246, 346)}.

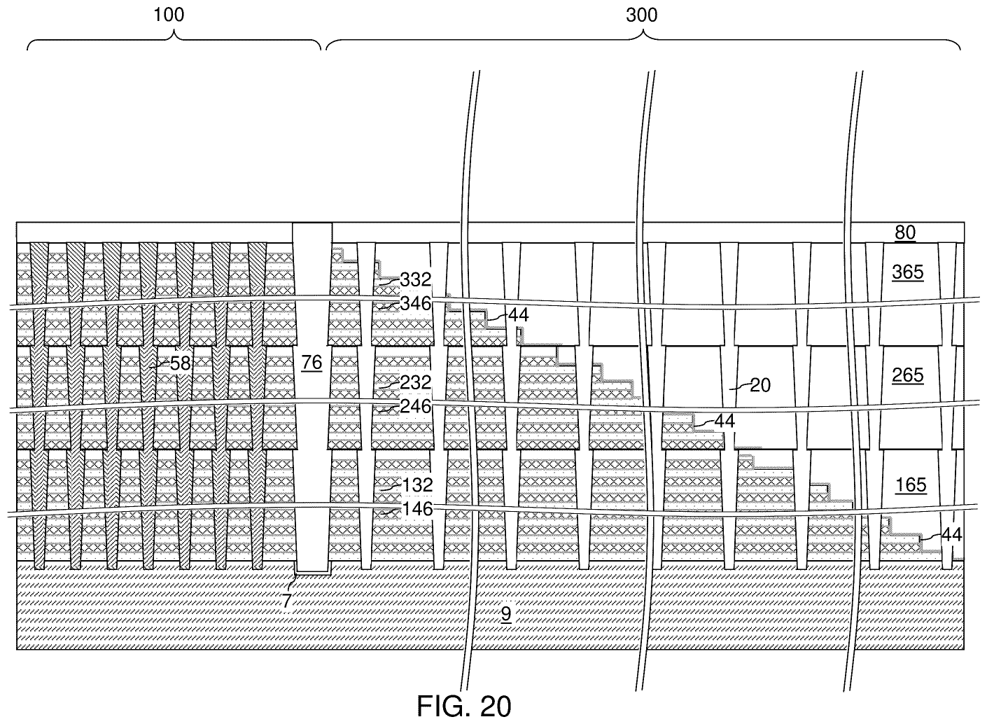

Referring to FIG. 20, an insulating fill material may be conformally deposited in the lateral isolation trenches 79. Excess portions of the insulating fill material may be removed from above the contact-level dielectric layer 80, for example, by a recess etch process. Each remaining portion of the insulating fill material that fills a respective lateral isolation trench 79 constitutes an lateral isolation trench fill structure 76. Alternatively, each lateral isolation trench fill structure 76 may comprise a combination of a tubular insulating spacer (not expressly shown) and a conductive connection via structure (not expressly shown) that is laterally surrounded by the tubular insulating spacer.

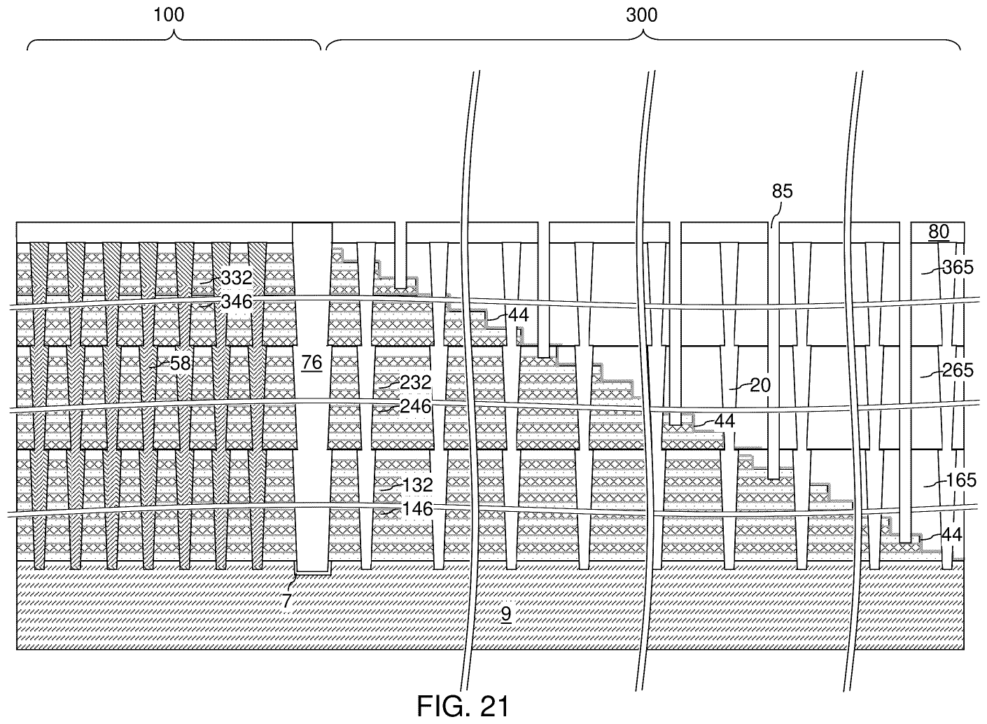

Referring to FIG. 21, a photoresist layer (not shown) can be applied over the contact-level dielectric layer 80, and can be lithographically patterned to form discrete opening therein over areas of the horizontally-extending surfaces of the stepped surfaces. An anisotropic etch process can be performed to transfer the pattern of the discrete openings in the photoresist layer through the contact-level dielectric layer 80 and the retro-stepped dielectric material portions (165, 265, 365).

In one embodiment, the anisotropic etch process includes a first anisotropic etch step that etches a material of the retro-stepped dielectric material portions (165, 265, or 365) selective to a material of the etch-stop dielectric layer portions 44E. Thus, the horizontally-extending segments 44E1 of the etch-stop dielectric layer portions 44E act as an etch stop during the first anisotropic etch, and prevent or reduce over etching of the openings through the electrically conductive layers (146, 246, 346). This prevents or reduces subsequent short circuiting of the electrically conductive layers by layer contact via structures. The anisotropic etch process also includes a second anisotropic etch step that etches the material of the horizontally-extending segments 44E1 of the etch-stop dielectric layer portion 44E (i.e., the material of the continuous etch-stop and blocking dielectric layer 44) selective to a material in the electrically conductive layers (146, 246, 346).

In an illustrative example, the contact-level dielectric layer 80 and the retro-stepped dielectric material portions (165, 265, 365) may comprise silicon oxide materials (such as undoped silicate glass (i.e., silicon oxide) and/or at least one doped silicate glass), and the continuous etch-stop and blocking dielectric layer 44 may comprise and/or may consist essentially of a dielectric metal oxide, such as aluminum oxide or a transition metal oxide. In this case, the first anisotropic etch step may employ CF₄ and/or CHF₃ in combination with O₂. The second anisotropic etch step etches the material of the continuous etch-stop and blocking dielectric layer 44 selective to a material in the electrically conductive layers (146, 246, 346). For example, the second anisotropic etch step may employ a combination of BCl₃, Cl₂, and Ar or a combination of SF₆ and O₂.

In one embodiment, the second anisotropic etch process may also etch through the insulating layers (132, 232, 332) overlying electrically conductive layers (146, 246, 346). In another embodiment, the anisotropic etch process also includes a third anisotropic etch step that etches the material of the insulating layers (132, 232, 332) selective to a material in the electrically conductive layers (146, 246, 346). In this case, the third anisotropic etch step may employ CF₄ and/or CHF₃ in combination with O₂ to selectively etch silicon oxide insulating layers (132, 232, 332).

Layer contact via cavities 85 can be formed through the contact-level dielectric layer 80, the retro-stepped dielectric material portions (165, 265, 365), the continuous etch-stop and blocking dielectric layer 44 and the insulating layers (132, 232, 332). Segments of top surfaces of the electrically conductive layers (146, 246, 346) are physically exposed underneath the layer contact via cavities 85. The photoresist layer can be removed, for example, by ashing.

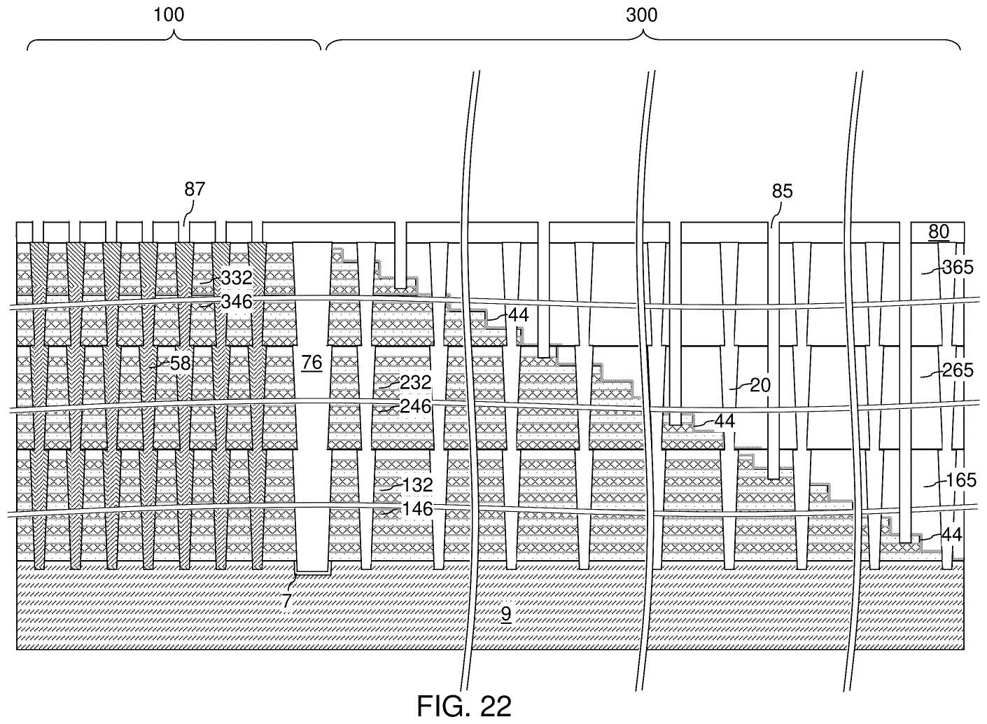

Referring to FIG. 22, a photoresist layer can be applied over the contact-level dielectric layer 80, and can be lithographically patterned to form openings over the memory opening fill structures 58. An anisotropic etch process can be performed to transfer the pattern of openings in the photoresist layer through the contact-level dielectric layer 80. Drain contact via cavities 87 can be formed through the contact-level dielectric layer 80. The photoresist layer can be removed, for example, by ashing. Alternatively, the drain contact via cavities 87 may be formed during the same anisotropic etching steps as the layer contact via cavities 85.

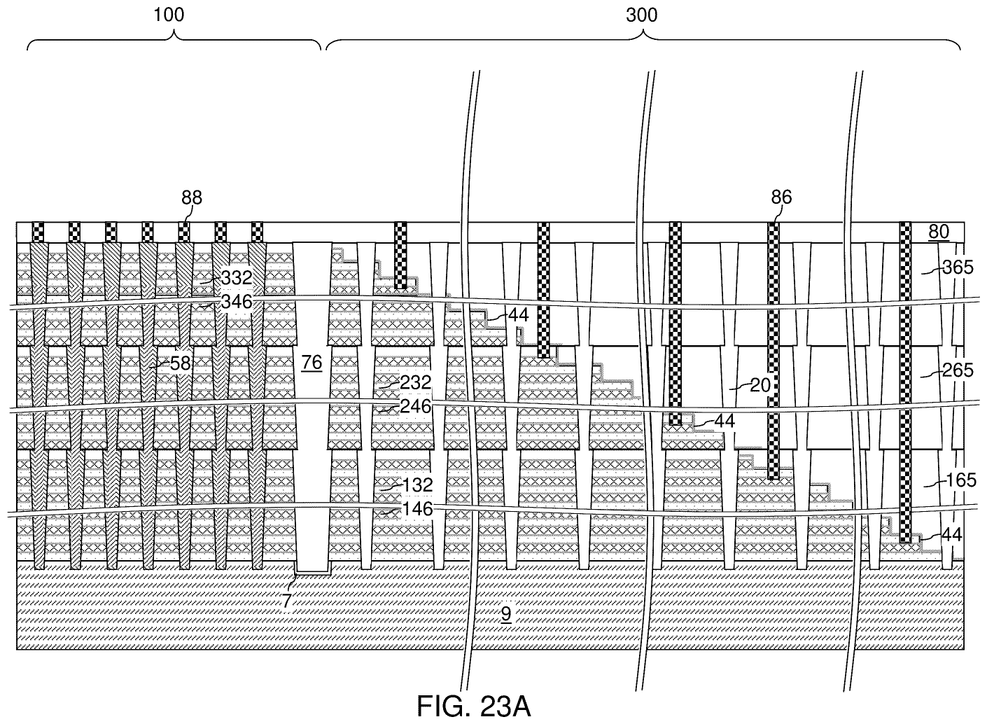

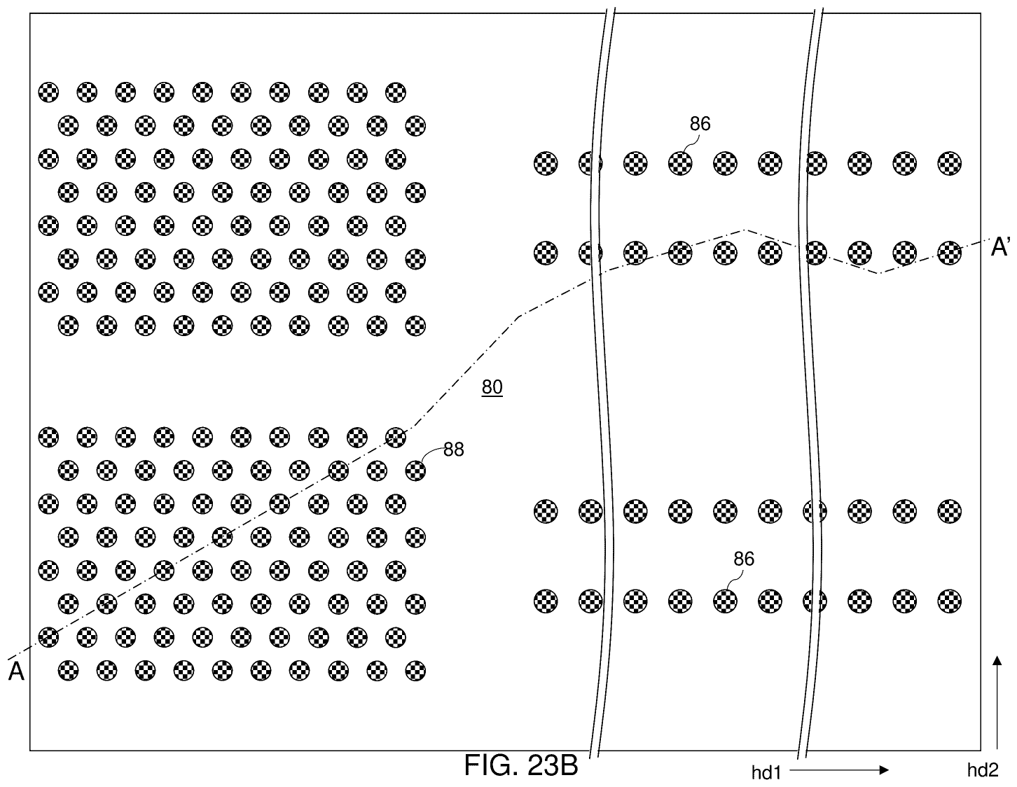

Referring to FIGS. 23A and 23B, at least one conductive material, such as a combination of an electrically conductive barrier material and an electrically conductive fill material, can be deposited in the drain contact via cavities 87 and the layer contact via cavities 85.

Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities 87 constitute drain contact via structures 88, which contact top surfaces of the drain regions 63. Remaining portions of the at least one conductive material that fill the layer contact via cavities 85 constitute layer contact via structures 86, which contact top surfaces of the electrically conductive layers (146, 246, 346). The layer contact via structures 86 have top surfaces within a same horizontal plane, such as the horizontal plane including the top surface of the contact-level dielectric layer 80. The layer contact via structures 86 vertically extend through the retro-stepped dielectric material portion (165, 265, or 365), through a respective horizontally-extending segment of the etch-stop dielectric layer portion 44E, and through the respective insulating layers (132, 232, 332), and contact a respective one of the electrically conductive layers (146, 246, 346).

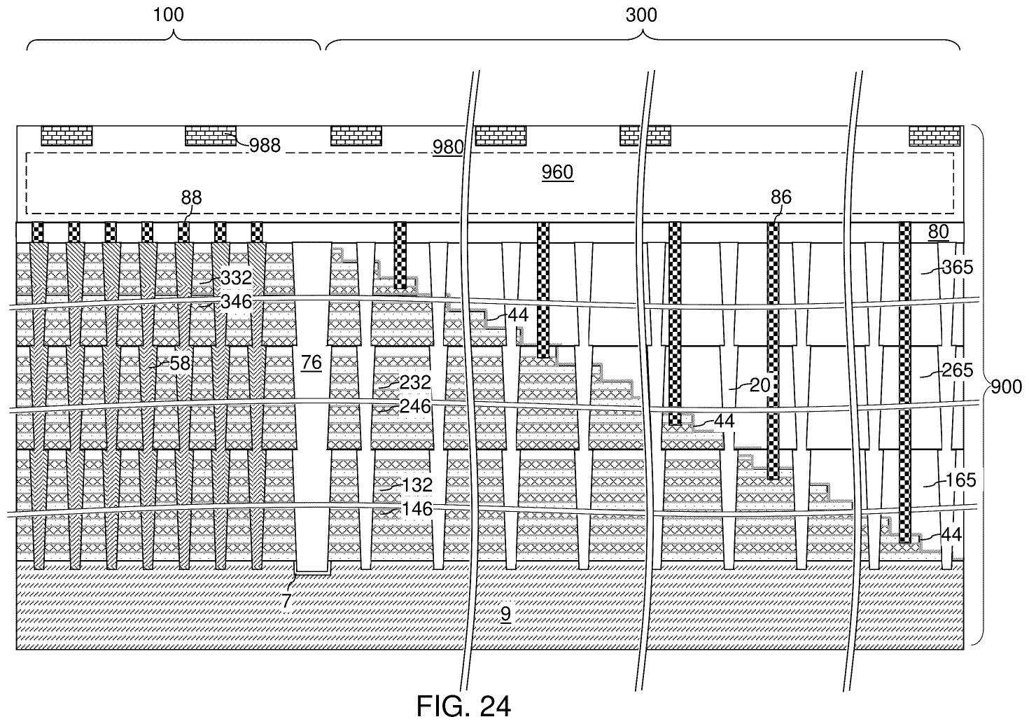

Referring to FIG. 24, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers (132, 232, 332) and electrically conductive layers (146, 246, 346) and the memory opening fill structures 58. A memory die 900 is formed by the above steps.

In one embodiment, the memory die 900 may comprise: a three-dimensional memory array comprising an alternating stack of insulating layers (132, 232, 332) and electrically conductive layers (146, 246, 346), a two-dimensional array of memory openings 49 vertically extending through the alternating stack, and a two-dimensional array of memory opening fill structures 58 located in the two-dimensional array of memory openings 49 and comprising a respective vertical stack of memory elements and a respective vertical semiconductor channel 60, a two-dimensional array of drain contact via structures 88 electrically connected to a respective one of the vertical semiconductor channels 60 via respective drain regions 63; and a two-dimensional array of layer contact via structures 86 electrically connected to a respective one of the electrically conductive layers (146, 246, 346), a subset of which functions as word lines for the three-dimensional memory array.

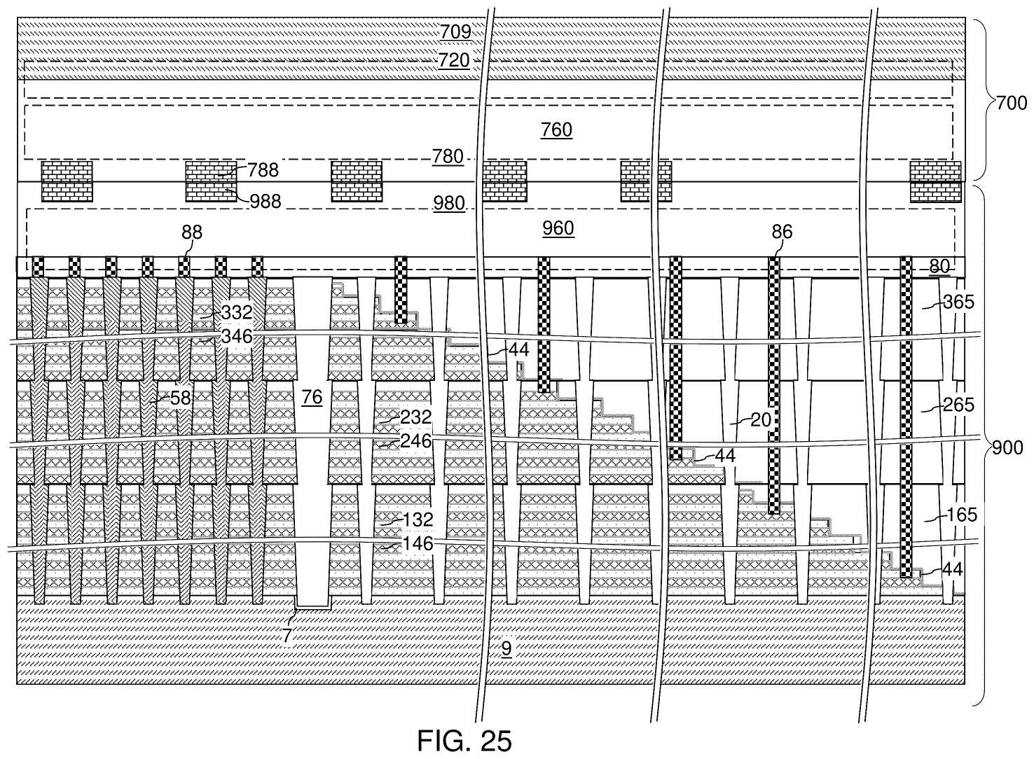

Referring to FIG. 25, a logic die 700 can be provided. For example, a peripheral circuit 720 can be formed on a logic-side substrate 709, which can be a semiconductor substrate. The peripheral circuit 720 can be configured to control operation of the memory array within the memory die 900. Logic-side metal interconnect structures 780 embedded within logic-side dielectric material layers 760 can be formed over the logic-side substrate 709 (which may comprise a semiconductor substrate) to form a logic die 700. The logic die 700 also comprises logic-side bonding pads 788 embedded within logic-side dielectric material layers 760.

A bonded assembly can be formed by bonding the logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

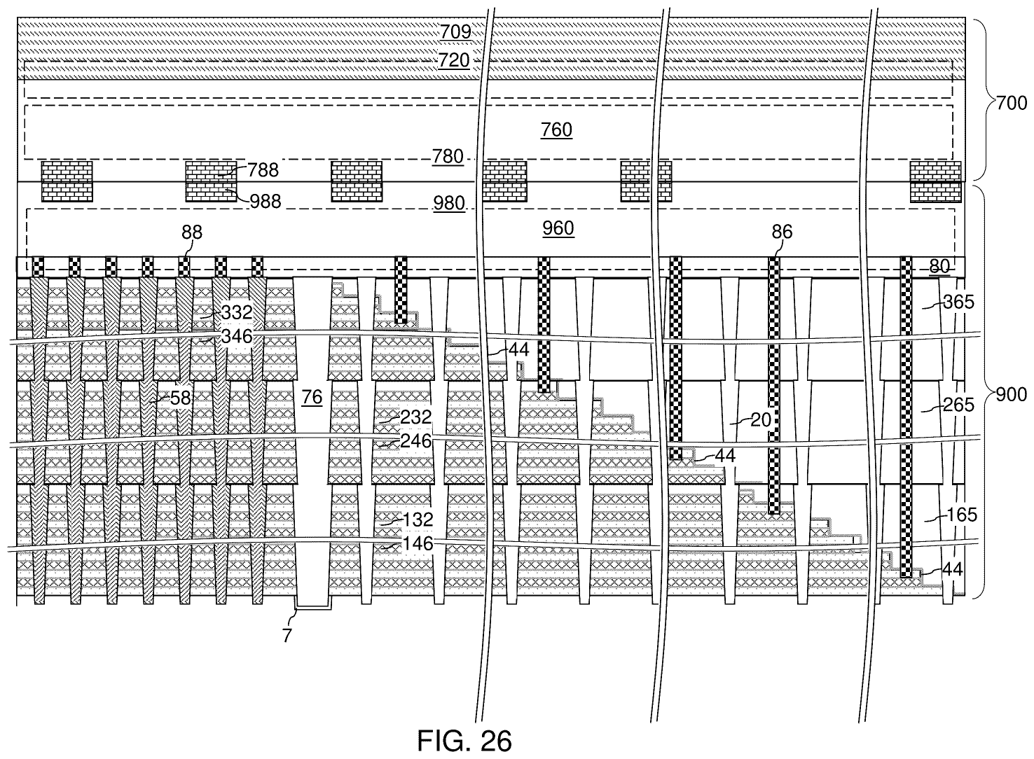

Referring to FIG. 26, the carrier substrate 9 can optionally be removed, for example, by grinding, polishing, cleaving, an isotropic etch process, and/or an anisotropic etch process.

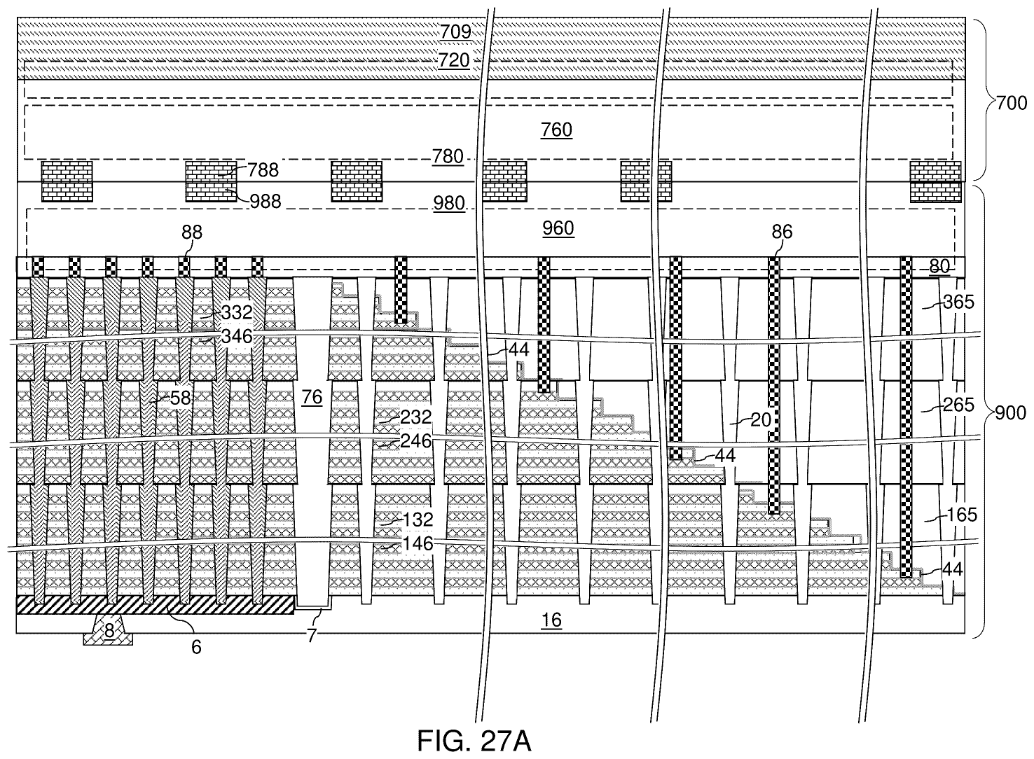

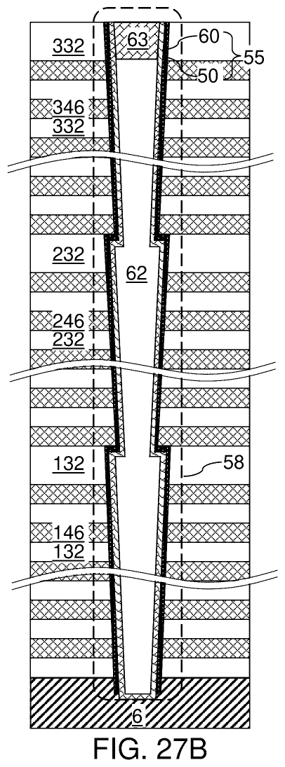

Referring to FIGS. 27A and 27B, end portions of the memory film 50 can be removed selective to the vertical semiconductor channel 60 from each memory opening fill structure 58, for example, by performing an etch process that etches the materials of the memory film 50 selective to the material of the vertical semiconductor channel 60.

At least one conductive material can be deposited on physically exposed surfaces of the vertical semiconductor channels 60, and can be subsequently patterned to form a source layer 6. The source layer 6 may comprise a heavily doped semiconductor material layer (e.g., heavily doped polysilicon) and/or a metallic layer, such as a metal (e.g., W, Ti, Ta, Mo, Al, etc.) and/or a conductive metal nitride (TiN, MoN, TaN, WN, etc.) A backside dielectric layer 16 can be deposited over the source layer 6 and physically exposed surfaces of the first alternating stack (132, 146). A source contact pad 8 can be formed on the source layer 6. The source layer 6 and the backside dielectric layer 16 may function as a base material layer for the various openings through the alternating stacks {(132, 146), (232, 246), (332, 346)}.

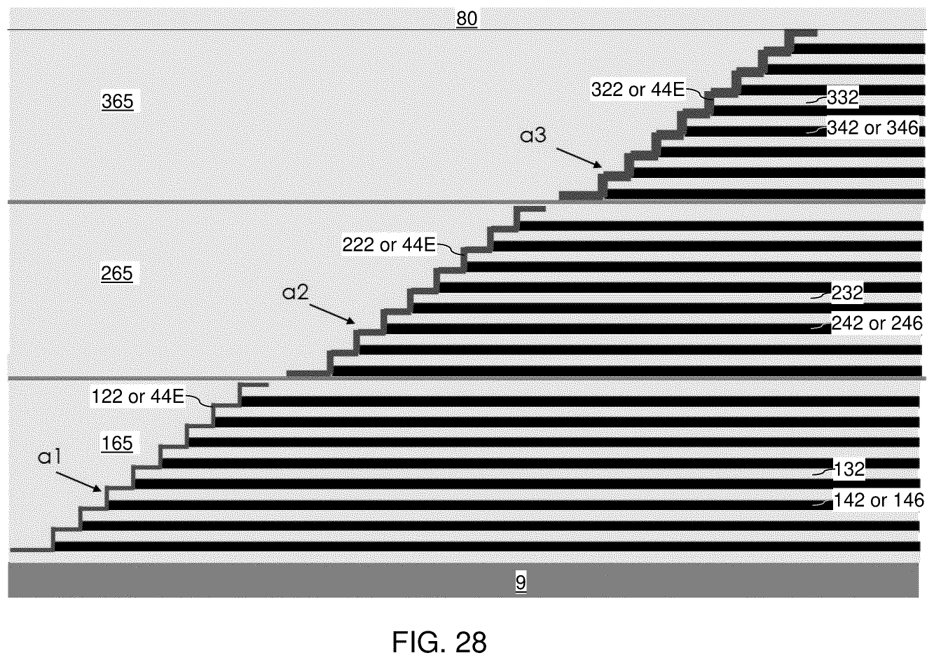

Referring to FIG. 28, a first alternative configuration of the exemplary structure is illustrated at a processing step, which may be equivalent to the processing step illustrated with reference to FIGS. 14A and 14B, or alternatively, may be equivalent to the processing step illustrated with reference to FIG. 20. Specifically, the illustrated first alternative configuration may represent a first structure in which a first stepped sacrificial liner 122, a second stepped sacrificial liner 222, a third stepped sacrificial liner 322, and sacrificial material layers (142, 242, 342) are present. The first structure corresponds to the processing step that is equivalent to the processing step illustrated with reference to FIGS. 14A and 14B. Alternatively, the illustrated first alternative configuration may represent a second structure in which the continuous etch-stop and blocking dielectric layer 44 and the electrically conductive layers (146, 246, 346) are present. The second structure corresponds to the processing step that is equivalent to the processing step illustrated with reference to FIG. 20. In this representation, the etch-stop dielectric layer portions 44E are illustrated, and the blocking dielectric layer portions 44B of the continuous etch-stop and blocking dielectric layer 44 are not illustrated for clarity.

The first alternative configuration illustrated in FIG. 28 can be derived from the exemplary structure described with reference to FIGS. 1-27B by employing different thicknesses among the first stepped sacrificial liner 122, the second stepped sacrificial liner 222, and the third stepped sacrificial liner 322. For example, the first stepped sacrificial liner 122 may have a first thickness a1, the second stepped sacrificial liner 222 may have a second thickness a2, the third stepped sacrificial liner 322 may have a third thickness a3. Thus, the third thickness a3 may be greater than the second thickness a2, and the second thickness a2 may be greater than the first thickness a1.

The third electrically conductive layers 346 are subjected to an anisotropic etch process that forms the layer contact via cavities 85 for a longer duration of time than the second electrically conductive layers 246, and the second electrically conductive layers 246 are subjected to an anisotropic etch process that forms the layer contact via cavities 85 for a longer duration of time than the first electrically conductive layers 146. The thicknesses of the stepped sacrificial liners (122, 222, 322) may be selected based on the expected duration of exposure of the underlying electrically conductive layers (146, 246, 346) during the anisotropic etch process. Thus, the third thickness a3 may be greater than the second thickness a2, and the second thickness a2 may be greater than the first thickness a1.

In an illustrative example, the third thickness a3 may be in a range from 10 nm to 20 nm, the second thickness a2 may be in a range from 5 nm to 12 nm, and the first thickness a1 may be in a range from 3 nm to 7 nm. Upon replacement of the stepped sacrificial liners (122, 222, 322) with etch-stop dielectric layer portions 44E, the etch-stop dielectric layer portions 44E may have different thicknesses in regions that replace different stepped sacrificial liners (122, 222, 322). Specifically, the region of the etch-stop dielectric layer portions 44E that replaces the first stepped sacrificial liner 122 may have the first thickness a1 as the first uniform thickness t1, the region of the etch-stop dielectric layer portions 44E that replaces the second stepped sacrificial liner 222 may have the second thickness a2 as the first uniform thickness t1, and the region of the etch-stop dielectric layer portions 44E that replaces the third stepped sacrificial liner 322 may have the third thickness a3 as the first uniform thickness t1.

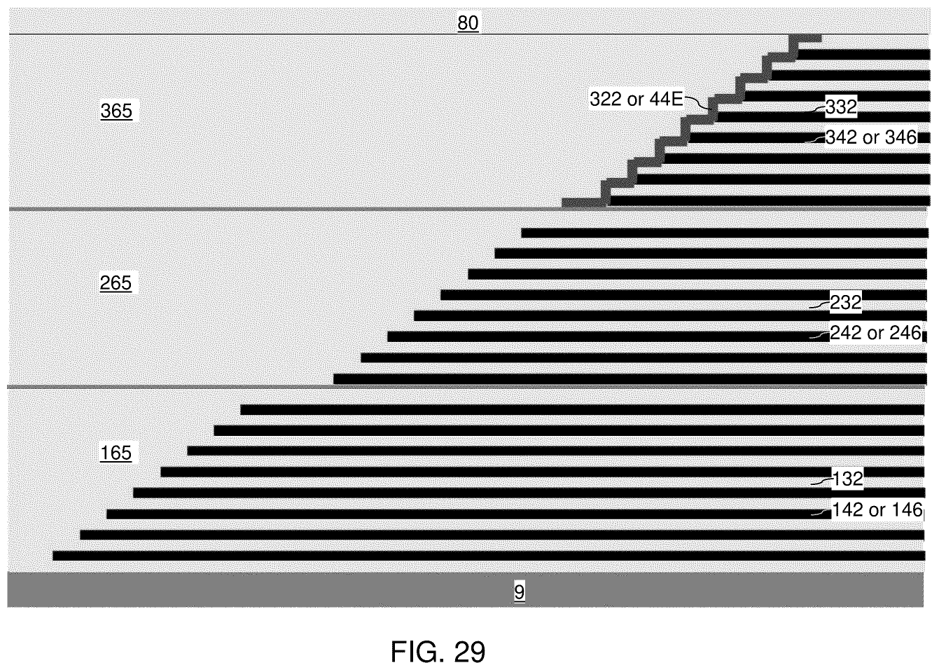

Referring to FIG. 29, a second alternative configuration of the exemplary structure is illustrated at a processing step, which may be equivalent to the processing step illustrated with reference to FIGS. 14A and 14B, or alternatively, may be equivalent to the processing step illustrated with reference to FIG. 20. Specifically, the illustrated second alternative configuration may represent a first structure in which a third stepped sacrificial liner 322 and sacrificial material layers (142, 242, 342) are present. The first structure corresponds to the processing step that is equivalent to the processing step illustrated with reference to FIGS. 14A and 14B. Alternatively, the illustrated second alternative configuration may represent a second structure in which the continuous etch-stop and blocking dielectric layer 44 and the electrically conductive layers (146, 246, 346) are present. The second structure corresponds to the processing step that is equivalent to the processing step illustrated with reference to FIG. 20. In this representation, the etch-stop dielectric layer portions 44E are illustrated, and the blocking dielectric layer portions 44B of the continuous etch-stop and blocking dielectric layer 44 are not illustrated.

The second alternative configuration illustrated in FIG. 29 can be derived from the exemplary structure described with reference to FIGS. 1-27B by omitting formation of the first stepped sacrificial liner 122, and the second stepped sacrificial liner 222, and by employing the third stepped sacrificial liner 322. In this case, the third electrically conductive layers 346 that are exposed to the longest duration of an anisotropic etch process during formation of the layer contact via cavities 85 can be protected by an etch-stop dielectric layer portion 44E, while etch-stop dielectric layer portions 44E are not formed over the second electrically conductive layers 246 or the first electrically conductive layers 146.

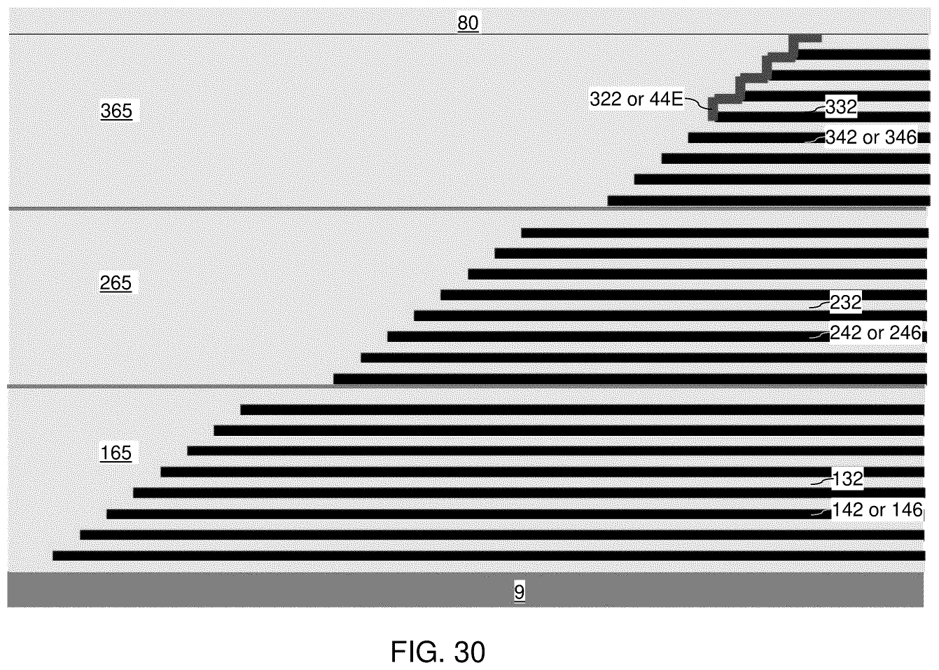

Referring to FIG. 30, a third alternative configuration of the exemplary structure is illustrated at a processing step, which may be equivalent to the processing step illustrated with reference to FIGS. 14A and 14B, or alternatively, may be equivalent to the processing step illustrated with reference to FIG. 20. Specifically, the illustrated second alternative configuration may represent a first structure in which a third stepped sacrificial liner 322 and sacrificial material layers (142, 242, 342) are present. The first structure corresponds to the processing step that is equivalent to the processing step illustrated with reference to FIGS. 14A and 14B. Alternatively, the illustrated third alternative configuration may represent a second structure in which the continuous etch-stop and blocking dielectric layer 44 and the electrically conductive layers (146, 246, 346) are present. The second structure corresponds to the processing step that is equivalent to the processing step illustrated with reference to FIG. 20. In this representation, the etch-stop dielectric layer portions 44E are illustrated, and the blocking dielectric layer portions 44B of the continuous etch-stop and blocking dielectric layer 44 are not illustrated.

The third alternative configuration illustrated in FIG. 30 can be derived from the second alternative configuration described with reference to FIG. 29 by patterning the third stepped sacrificial liner 322 such that the third stepped sacrificial liner 322 is formed only on a subset of the layers within the third alternating stack (332, 342) that is located in an upper portion of the third alternating stack (332, 342). In this case, an upper subset of the third electrically conductive layers 346 that are exposed to the longest duration of an anisotropic etch process during formation of the layer contact via cavities 85 can be protected by an etch-stop dielectric layer portion 44E, while etch-stop dielectric layer portions 44E are not formed over a subset of the third electrically conductive layers 346 located in a lower portion of a third alternating stack (332, 346), the second electrically conductive layers 246, or the first electrically conductive layers 146.

Referring to all drawings and according to various embodiments of the present disclosure, a device structure comprises: an alternating stack {(132, 232, 332), (146, 246, 346)} of insulating layers (132, 232, 332) and electrically conductive layers (146, 246, 346) that alternate along a vertical direction, wherein lateral extents of the electrically conductive layers (146, 246, 346) vary in a staircase region 300; memory openings 49 vertically extending through the alternating stack {(132, 232, 332), (146, 246, 346)}; memory opening fill structures 58 located in the memory openings 49, wherein each of the memory opening fill structures 58 comprises a respective vertical stack of memory elements (e.g., portions of the memory film 50) and a vertical semiconductor channel 60; and a continuous metal oxide etch-stop and blocking dielectric layer 44 including blocking dielectric layer portions 44B and an etch-stop dielectric layer portion 44E, wherein the etch-stop dielectric layer portion 44E continuously extends over a least a portion of the alternating stack {(132, 232, 332), (146, 246, 346)} in the staircase region 300 with a stepped vertical cross-sectional profile.

In one embodiment, each of the blocking dielectric layer portions 44B comprises a respective pair of horizontally-extending blocking dielectric layer segments (44B1, 44B2) joined by a respective set of tubular blocking dielectric layer segments 44B3 that laterally surround a respective one of the memory opening fill structures 58.

In one embodiment, each of the electrically conductive layers (146, 246, 346) comprises: a planar top surface an entirety of which is contacted by an upper horizontally-extending blocking dielectric layer segment 44B1 within a respective blocking dielectric layer portion 44B; and a planar bottom surface an entirety of which is contacted by a lower horizontally-extending blocking dielectric layer segment 44B2 within the respective blocking dielectric layer portion 44B.

In one embodiment, all horizontally-extending segments 44E1 of the etch-stop dielectric layer portion 44E have a first uniform thickness t1, and all horizontally-extending segments (44B1, 44B2) and all vertically-extending segments 44B3 of the blocking dielectric layer portions 44B have a second uniform thickness t2, wherein the first uniform thickness t1 is greater than the second uniform thickness t2. In one embodiment, first vertically-extending segments 44E2 of the etch-stop dielectric layer portion 44E have the first uniform thickness t1; and second vertically-extending segments 44E3 of the etch-stop dielectric layer portion 44E have the second uniform thickness t2.

In one embodiment, a retro-stepped dielectric material portion (165, 265, 365) is located in the staircase region 300 over the etch-stop dielectric layer portion 44E, and the etch-stop dielectric layer portion 44E is in contact with horizontal surface segments and vertical surface segments of a retro-stepped dielectric material portion (165, 265, 365).

In one embodiment, each neighboring pair of horizontally-extending segments 44E1 of the etch-stop dielectric layer portion 44E is joined to each other by a combination of a respective one of the first vertically-extending segments 44E2 of the etch-stop dielectric layer portion 44E and a respective one of the second vertically-extending segments 44E3 of the etch-stop dielectric layer portion 44E. In one embodiment, each of the first vertically-extending segments 44E2 of the etch-stop dielectric layer portion 44E contacts a sidewall of a respective one of the insulating layers (132, 232, 332) within the alternating stack {(132, 232, 332), (146, 246, 346)}; and each of the second vertically-extending segments 44E3 of the etch-stop dielectric layer portion 44E contacts a sidewall of a respective one of the electrically conductive layers (146, 246, 346) within the alternating stack {(132, 232, 332), (146, 246, 346)}.

In one embodiment, each of the electrically conductive layers (146, 246, 346) comprises: a respective metallic barrier liner 46B in contact with a respective one of the blocking dielectric layer portions 44B and in contact with a respective vertically-extending segment of the etch-stop dielectric layer portion 44E; and a respective metallic fill material portion 46F that is embedded within the respective metallic barrier liner 46B and spaced from the continuous etch-stop and blocking dielectric layer 44 by the respective metallic barrier liner 46B. In one embodiment, the continuous metal oxide etch-stop and blocking dielectric layer 44 comprises aluminum oxide.

In one embodiment, the device structure further comprises a retro-stepped dielectric material portion (165, 265, or 365) comprising a stepped bottom surface that overlies and is in contact with the etch-stop dielectric layer portion 44E. Each of the insulating layers (132, 232, 332) is laterally spaced from the retro-stepped dielectric material portion (165, 265, or 365) by a respective first vertically-extending segment 44E2 of the etch-stop dielectric layer portion 44E having a first uniform thickness t1; and each of the electrically conductive layers (146, 246, 346) is laterally spaced from the retro-stepped dielectric material portion (165, 265, or 365) by a respective second vertically-extending segment 44E3 of the etch-stop dielectric layer portion 44E having a second uniform thickness t2 that is less than the first uniform thickness t1.

In one embodiment, each of the insulating layers (132, 232, 332) is vertically spaced from a respective overlying portion of the retro-stepped dielectric material portion (165, 265, or 365) by a respective horizontally-extending segment 44E1 of the etch-stop dielectric layer portion 44E having the first uniform thickness t1.

In one embodiment, the device structure further comprises layer contact via structures 86 having top surfaces within a same horizontal plane, vertically extending through the retro-stepped dielectric material portion (165, 265, or 365), through a respective horizontally-extending segment of the etch-stop dielectric layer portion 44E, and through a respective one of the insulating layers (132, 232, 332), and contacting a respective one of the electrically conductive layers (146, 246, 346). In one embodiment, the horizontally-extending segments 44E1 of the etch-stop dielectric layer portion 44E have a first uniform thickness t1 that is less than a vertical spacing between neighboring pairs of the insulating layers (132, 232, 332) within the alternating stack {(132, 232, 332), (146, 246, 346)}.

The etch-stop dielectric layer portions 44E prevent or reduce over etching of electrically conductive layers (146, 246, 346) during formation of the layer contact via cavities 85. The etch-stop dielectric layer portions 44E are formed as self-aligned structures through replacement of at least one stepped sacrificial liner (122, 222, 322). Deleterious electrical shorting of electrically conductive layers (146, 246, 346) by layer contact via structures 86 can be prevented or reduce through use of the etch-stop dielectric layer portions 44E.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
an alternating stack of insulating layers and electrically conductive layers that alternate along a vertical direction, wherein lateral extents of the electrically conductive layers vary in a staircase region;
memory openings vertically extending through the alternating stack;
memory opening fill structures located in the memory openings, wherein each of the memory opening fill structures comprises a respective vertical stack of memory elements and a vertical semiconductor channel; and
a continuous metal oxide etch-stop and blocking dielectric layer including blocking dielectric layer portions and an etch-stop dielectric layer portion, wherein the etch-stop dielectric layer portion continuously extends over at least a portion of the alternating stack in the staircase region with a stepped vertical cross-sectional profile.

2. The device structure of claim 1, wherein each of the blocking dielectric layer portions comprises a respective pair of horizontally-extending blocking dielectric layer segments joined by a respective set of tubular blocking dielectric layer segments that laterally surround a respective one of the memory opening fill structures.

3. The device structure of claim 2, wherein each of the electrically conductive layers comprises:
a planar top surface an entirety of which is contacted by an upper horizontally-extending blocking dielectric layer segment within a respective blocking dielectric layer portion; and
a planar bottom surface an entirety of which is contacted by a lower horizontally-extending blocking dielectric layer segment within the respective blocking dielectric layer portion.

4. The device structure of claim 2, wherein:
all horizontally-extending segments of the etch-stop dielectric layer portion have a first uniform thickness; and
all horizontally-extending segments and all vertically-extending segments of the blocking dielectric layer portions have a second uniform thickness, wherein the first uniform thickness is greater than the second uniform thickness.

5. The device structure of claim 4, further comprising a retro-stepped dielectric material portion located in the staircase region over the etch-stop dielectric layer portion, wherein the etch-stop dielectric layer portion is in contact with horizontal surface segments and vertical surface segments of a retro-stepped dielectric material portion.

6. The device structure of claim 4, wherein:
first vertically-extending segments of the etch-stop dielectric layer portion have the first uniform thickness; and
second vertically-extending segments of the etch-stop dielectric layer portion have the second uniform thickness.

7. The device structure of claim 6, wherein each neighboring pair of horizontally-extending segments of the etch-stop dielectric layer portion is joined to each other by a combination of a respective one of the first vertically-extending segments of the etch-stop dielectric layer portion and a respective one of the second vertically-extending segments of the etch-stop dielectric layer portion.

8. The device structure of claim 6, wherein:
each of the first vertically-extending segments of the etch-stop dielectric layer portion contacts a sidewall of a respective one of the insulating layers within the alternating stack; and
each of the second vertically-extending segments of the etch-stop dielectric layer portion contacts a sidewall of a respective one of the electrically conductive layers within the alternating stack.

9. The device structure of claim 1, wherein the continuous metal oxide etch-stop and blocking dielectric layer comprises aluminum oxide.

10. The device structure of claim 1, further comprising a retro-stepped dielectric material portion comprising a stepped bottom surface that overlies and is in contact with the etch-stop dielectric layer portion, wherein:
each of the insulating layers is laterally spaced from the retro-stepped dielectric material portion by a respective first vertically-extending segment of the etch-stop dielectric layer portion having a first uniform thickness; and
each of the electrically conductive layers is laterally spaced from the retro-stepped dielectric material portion by a respective second vertically-extending segment of the etch-stop dielectric layer portion having a second uniform thickness that is less than the first uniform thickness.

11. The device structure of claim 10, wherein each of the insulating layers is vertically spaced from a respective overlying portion of the retro-stepped dielectric material portion by a respective horizontally-extending segment of the etch-stop dielectric layer portion having the first uniform thickness.

12. The device structure of claim 10, further comprising layer contact via structures having top surfaces within a same horizontal plane, vertically extending through the retro-stepped dielectric material portion, through a respective horizontally-extending segment of the etch-stop dielectric layer portion, and through a respective one of the insulating layers, and contacting a respective one of the electrically conductive layers.

13. The device structure of claim 2, wherein the horizontally-extending segments of the etch-stop dielectric layer portion have a first uniform thickness that is less than a vertical spacing between neighboring pairs of the insulating layers within the alternating stack.

14. A method of forming a device structure, comprising:
forming an alternating stack of insulating layers and sacrificial material layers over a substrate;
forming stepped surfaces by pattering the alternating stack;
forming a stepped sacrificial liner on the stepped surfaces of the alternating stack;
forming a retro-stepped dielectric material portion over the stepped sacrificial liner;
forming memory stack structures through the alternating stack;
forming a continuous void including laterally-extending cavities and a staircase-shaped cavity by removing the sacrificial material layers and the stepped sacrificial liner, wherein the laterally-extending cavities comprise voids formed by removal of the sacrificial material layers and the staircase-shaped cavity comprises a void formed by removal of the stepped sacrificial liner;
forming a continuous etch-stop and blocking dielectric layer including blocking dielectric layer portions and an etch-stop dielectric layer portion having a stepped vertical cross-sectional profile, and each of the blocking dielectric layer portions is formed in a peripheral region of a respective one of the laterally-extending cavities; and
forming electrically conductive layers in remaining unfilled volumes of the laterally-extending cavities.

15. The method of claim 14, further comprising:
forming layer contact via cavities by performing an anisotropic etch process that includes a first anisotropic etch step that etches a material of the retro-stepped dielectric material portion selective to a material of the etch-stop dielectric layer portion, and further includes a second anisotropic etch step that etches the material of the etch-stop dielectric layer portion selective to a material in the electrically conductive layers; and
forming layer contact via structures in the layer contact via cavities by filling the layer contact via cavities with at least one conductive material.

16. The method of claim 14, further comprising:
forming a lateral isolation trench through the alternating stack; and
performing an isotropic etch process employing an isotropic etchant that etches materials of the sacrificial material layers and the stepped sacrificial liner selective to a material of the insulating layers to form the continuous void.

17. The method of claim 14, further comprising:
conformally depositing a dielectric liner material within the staircase-shaped cavity and in peripheral portions of the laterally-extending cavities, wherein a thickness of the deposited dielectric liner material in the peripheral portions of the laterally-extending cavities is greater than one half of a thickness of the stepped sacrificial liner; and
isotropically etching back the dielectric liner material by a recess etch distance that is less than the thickness of the deposited dielectric liner material in the peripheral portions of the laterally-extending cavities, wherein remaining portions of the deposited dielectric liner material comprise the continuous etch-stop and blocking dielectric layer.

18. The method of claim 14, wherein:
all horizontally-extending segments of the etch-stop dielectric layer portion have a first uniform thickness;
all horizontally-extending segments and all vertically-extending segments of the blocking dielectric layer portions have a second uniform thickness; and
the first uniform thickness is greater than the second uniform thickness.

19. The method of claim 18, wherein:
first vertically-extending segments of the etch-stop dielectric layer portion have the first uniform thickness;
second vertically-extending segments of the etch-stop dielectric layer portion have the second uniform thickness; and
each neighboring pair of horizontally-extending segments of the etch-stop dielectric layer portion is joined to each other by a combination of a respective one of the first vertically-extending segments of the etch-stop dielectric layer portion and a respective one of the second vertically-extending segments of the etch-stop dielectric layer portion.

20. The method of claim 14, wherein:
the memory stack structures each comprise a vertical semiconductor channel and a vertical stack of memory elements;
the sacrificial material layers and the stepped sacrificial liner comprise silicon nitride; and
the continuous etch-stop and blocking dielectric layer comprises aluminum oxide.
